(19) United States
(12) Patent Application Publication
(10) Pub. No.: US 2022/0153920 A1
(43) Pub. Date: May 19, 2022

(54) METHOD FOR PRODUCING POLYMER

(71) Applicant: NISSAN CHEMICAL CORPORATION, Tokyo (JP)

(72) Inventors: Yutaro TSUDA, Toyama-shi (JP); Hiroki YAMAGUCHI, Toyama-shi (JP)

(73) Assignee: NISSAN CHEMICAL CORPORATION, Tokyo (JP)

(21) Appl. No.: 17/430,833

(22) PCT Filed: Feb. 12, 2020
(86) PCT No.: PCT/JP2020/005232

§ 371 Date: Aug. 13, 2021

(30) Foreign Application Priority Data
Feb. 14, 2019 (JP) 2019-024362

(51) Int. Cl. C08G 59/26; G03F 7/11; C08G 59/68

(52) U.S. Cl. CPC C08G 59/26; C08G 59/688; G03F 7/11

(57) ABSTRACT

Provided is a method for producing a polymer, characterized by reacting (A) an epoxy compound having two or more epoxy groups in the molecule with (B) a reactive compound having, in the molecule, two or more functional groups reactive with epoxy groups, in the presence of (C) a polymerization catalyst and (D) a cocatalyst.

### TECHNICAL FIELD

The present invention relates to a method for producing a polymer by reacting an epoxy compound having two or more epoxy groups in the molecule with a reactive compound having two or more functional groups that react with the epoxy groups in the molecule.

### BACKGROUND ART

In general, the molecular weight of a polymer has a significant effect on physical properties, and therefore control of the molecular weight can be a common problem in production of a polymer. In production of a polymer by reacting at least one diepoxy compound with a compound having two or more reactive functional groups (reactive compound), a method as described in Non-Patent Document 1 is known as a general method. Heretofore, for controlling the molecular weight of the polymer to be within an intended range, a method has been adopted in which the reaction time is strictly managed, and a polymerization reaction is forcibly stopped by performing cooling at the time when an intended molecular weight is achieved. However, in this method, it takes much time for cooling and it is difficult to control the polymer to have an intended molecular weight with high reproducibility when the scale of production is expanded. In addition, for example, in the case where cooling is delayed because the scale is excessively large or a trouble occurs in a cooling apparatus, there is a risk that the molecular weight becomes excessively large, so that the viscosity of a reaction liquid increases, leading to breakage of a stirring blade of a reactor.

On the other hand, as a method for suppressing an increase in molecular weight, there is a method in which in general, the equivalent ratio of the diepoxy monomer and the reactive monomer is significantly shifted from 1:1 (e.g. 1:1.2), and in this method, a significant increase in molecular weight can be suppressed, but an intended molecular weight cannot be stabilized, and an excess of monomers added remain in the system, so that purification step for removing residual monomers is essential, which is not preferable from the viewpoint of productivity.

### PRIOR ART DOCUMENTS

### Non-Patent Documents

Non-Patent Document 1: Collection of Papers on Polymer. Vol. 53, No. 9, p. 522-529, (1996)

### SUMMARY OF INVENTION

### Technical Problem

The present invention has been made in view of the above-described circumstances, and an object of the present invention is to provide a method for producing a polymer, which can accurately control the molecular weight to an intended molecular weight and stabilize the molecular weight without continuously increasing the molecular weight in a reaction system of an epoxy compound having two or more epoxy groups in the molecule and a reactive compound having two or more functional groups reactive with an epoxy group in the molecule.

### Solution to Problem

The present inventors have extensively conducted studies for achieving the above-described object, and resultantly found a method in which when in reaction of an epoxy compound having two or more epoxy groups in the molecule with a reactive compound having two or more functional groups reactive with an epoxy group in the molecule, two or more kinds of catalysts including a polymerization catalyst and a catalyst different from the polymerization catalyst (co-catalyst) are added, the molecular weight can be accurately controlled to an intended molecular weight and the molecular weight can be stabilized without continuously increasing the molecular weight in this reaction system, leading to completion of the present invention.

That is, the present invention provides the following method for producing a polymer.

1. A method for producing a polymer, including reacting (A) an epoxy compound having two or more epoxy groups in a molecule with (B) a reactive compound having two or more functional groups reactive with an epoxy group in the molecule, in the presence of (C) a polymerization catalyst and (D) a co-catalyst.
2. The method for producing a polymer according to 1, wherein the component (C) is an onium salt having one or more quaternary Group 15 element structures.
3. The method for producing a polymer according to 2, wherein the Group 15 element of the component (C) is nitrogen or phosphorus.
4. The method for producing a polymer according to 2 or 3, wherein a substituent in the Group 15 element structure of the component (C) is at least one selected from an alkyl group having 1 to 20 carbon atoms, an aryl group having 6 to 20 carbon atoms, and an aralkyl group having 7 to 20 carbon atoms.
5. The method for producing a polymer according to any one of 2 to 4, wherein a counter anion in the onium salt is selected from a halide ion, a nitrate ion, a sulfate ion, an acetate ion, a formate ion, a hydroxide ion, and a sulfonate ion having an alkyl group having 1 to 20 carbon atoms or an aryl group having 6 to 20 carbon atoms.
6. The method for producing a polymer according to any one of 1 to 5, wherein the component (D) is a compound having a primary to tertiary Group 15 element structure or a heteroaryl compound containing a Group 15 element in an aromatic ring.
7. The method for producing a polymer according to 6, wherein the Group 15 element of the component (D) is nitrogen or phosphorus.
8. The method for producing a polymer according to 6 or 7, wherein the component (D) is a compound having a tertiary Group 15 element structure or a heteroaryl compound containing a Group 15 element in the aromatic ring.
9. The method for producing a polymer according to any one of 6 to 8, wherein a substituent in the Group 15 element structure of the component (D) is at least one selected from an alkyl group having 1 to 20 carbon atoms, an aryl group having 6 to 20 carbon atoms, and an aralkyl group having 7 to 20 carbon atoms.
10. The method for producing a polymer according to any one of 1 to 9, wherein the component (A) is one or more selected from a diepoxy compound, a triepoxy compound, a tetraepoxy compound, and a polymer having an epoxy group.
11. The method for producing a polymer according to any one of 1 to 10, wherein the functional group of the component (B) is a hydroxyl group, a formyl group, a carboxy group, an amino group, an imino group, an azo group, an azi group, a thiol group, a sulfo group, an amide group, an imide group, a thiocarboxy group, a dithiocarboxy group, a phosphate group, a phosphite group, a phosphonate group, a phosphonite group, a phosphinate group, a phosphinite group, a phosphine group, an acid anhydride or an acid chloride.
12. The method for producing a polymer according to any one of 1 to 11, wherein an equivalent ratio of epoxy groups of the component (A) to functional groups of the component (B) is 0.1:1.0 to 1.0:0.1 in terms of (A):(B).
13. The method for producing a polymer according to any one of 1 to 12, wherein a compounding ratio (molar ratio) of the component (C) to the component (D) is 0.1:1.0 to 1.0:0.1, and a total amount of the component (C) and the component (D) is 0.0001 to 0.5 mol per 1 mol of the component (A).
14. The method for producing a polymer according to any one of 1 to 13, wherein further, one or more selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone. N,N-dimethylformamide and N,N-dimethylacetamide are used as organic solvents.
15. The method for producing a polymer according to 14, wherein an amount of the organic solvent used is 0.1 to 100 parts by weight per 1.0 part by weight of the component (A).
16. The method for producing a polymer according to any one of 1 to 15, wherein a reaction temperature is 25 to 200° C.
17. A method for producing a resist lower layer film forming composition, the method including mixing a polymer obtained by the production method according to any one of 1 to 16 with an organic solvent.

### Advantageous Effects of Invention

By the method for producing a polymer according to the present invention, the weight average molecular weight of an intended polymer can be easily controlled, and a polymer having a desired weight average molecular weight can be produced with good producibility.

### DESCRIPTION OF EMBODIMENTS

The method for producing a polymer includes reacting (A) an epoxy compound having two or more epoxy groups in the molecule with (B) a reactive compound having two or more functional groups reactive with an epoxy group in the molecule, under the coexistence of (C) a polymerization catalyst and (D) a co-catalyst.

In the present invention, the (A) epoxy compound having two or more epoxy groups in the molecule is preferably a diepoxy compound, a triepoxy compound, a tetraepoxy compound or a polymer having an epoxy group, more preferably a diepoxy compound or a triepoxy compound, still more preferably a diepoxy compound in view of accurately controlling the weight average molecular weight of the resulting polymer.

In the present invention, the weight average molecular weight is a value in terms of polystyrene measured by gel permeation chromatography (GPC).

Examples of preferable compounds as the diepoxy compound, the triepoxy compound and the tetraepoxy compound of the component (A) include compounds of the following formulae (A1) to (A9).

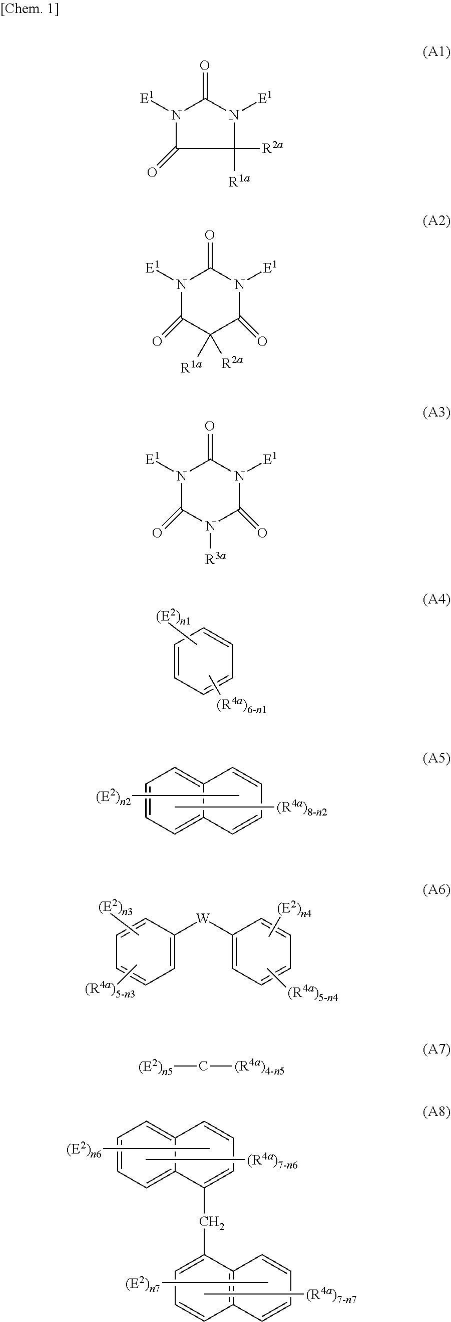

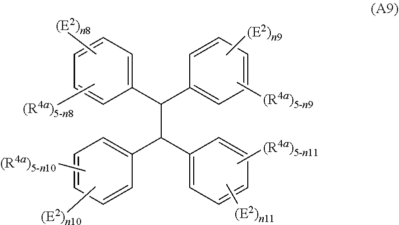

In the formulae (A1) to (A3), E¹ is a group of the following formula (a-1).

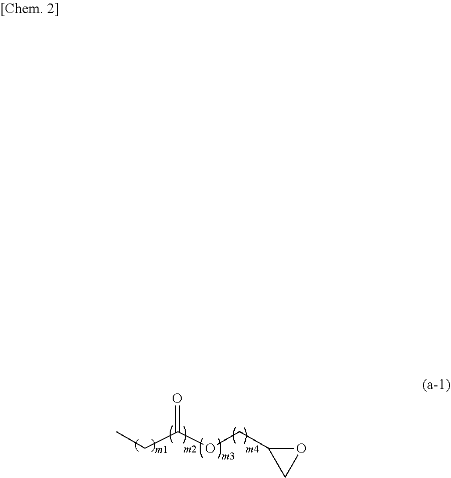

wherein m1 is an integer of 0 to 4, m2 is 0 or 1, m3 is 0 or 1, m4 is 1 or 2, and both m1 and m2 are not 0 when m3 is 1.

In the formulae (A1) and (A2), R^{1a} and R^{2a} each independently represent a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms optionally interrupted by an oxygen atom or a sulfur atom, a benzyl group, or a phenyl group, and the phenyl group is optionally substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms.

In the formula (A3), R^{3a} represents a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms optionally interrupted by an oxygen atom or a sulfur atom, a benzyl group, a phenyl group, or E¹, and the phenyl group is optionally substituted with at least one monovalent group selected from an alkyl group having 1 to 10 carbon atoms, a halogen atom, an alkoxy group having 1 to 6 carbon atoms, a nitro group, a cyano group, and an alkylthio group having 1 to 6 carbon atoms.

Examples of the alkyl group having 1 to 10 carbon atoms include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2 methyl-cyclopropyl group and a 2-ethyl-3-methyl-cyclopropyl group.

Examples of the alkenyl group having 2 to 10 carbon atoms include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a4-methyl-2-pentenyl group, a 4-methyl-3-pentenyl group, a4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, 1-cyclohexenyl group, a 2-cyclohexenyl group and a 3-cyclohexenyl group.

Examples of the alkynyl group having 2 to 10 carbon atoms include an ethynyl group, a 1-propynyl group, a 2-propynyl group, a 1-butynyl group, a 2-butynyl group, a 3-butynyl group, a 4-methyl-1-pentynyl group and a 3-methyl-1-pentynyl group.

The phrase “optionally interrupted by an oxygen atom or a sulfur atom” means that, for example, a carbon atom in the middle of a saturated carbon chain of the alkyl group, alkenyl group, and alkynyl group is replaced by an oxygen atom or a sulfur atom. For example, when any carbon atom is replaced by an oxygen atom in an alkyl group, an alkenyl group and an alkynyl group, an ether bond is present, and when any carbon atom is replaced by a sulfur atom in such groups, a thioether bond is present.

Examples of the halogen atom include fluorine, chlorine, bromine and iodine atoms.

Examples of the alkoxy group having 1 to 6 carbon atoms include a methoxy group, an ethoxy group, a n-propoxy group, an i-propoxy group, a n-butoxy group, an i-butoxy group, a s-butoxy group, a t-butoxy group, a n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group and a 1-ethyl-2-methyl-n-propoxy group.

Examples of the alkylthio group having 1 to 6 carbon atoms include an ethylthio group, a butylthio group and a hexylthio group.

In the formulae (A4) to (A9). R^{4a} each independently represents a hydrogen atom, an alkyl group having 1 to 10 carbon atoms, or an alkenyl group having 2 to 10 carbon atoms, and —W— represents a single bond, —CH₂—, —C(CH₃)₂—, —C(CF₃)₂—, —CO—, —O—, —S— or —SO₂—, n1 represents an integer of 2 to 4. n2 represents an integer of 2 to 4. n3 and n4 each independently represent an integer of 0 to 4, where n3+n4 is 2 to 4. n5 represents an integer of 2 to 4. n6 and n7 each independently represent an integer of 0 to 4, where n6+n7 is 2 to 4. n8 to n11 each independently represent an integer of 0 to 4, where n8+n9+n10+n11 is 2 to 4.

In the formulae (A4) to (A9), E² represents a group of the following formula (a-2).

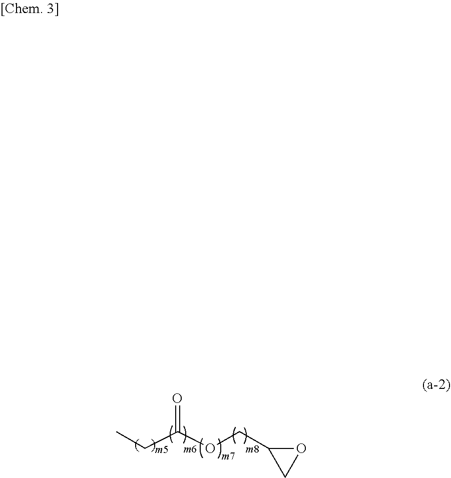

In the formula, m5 is an integer of 0 to 4, m6 is 0 or 1, m7 is 0 or 1, and m8 is 1 or 2.

Examples of the alkyl group having 1 to 10 carbon atoms and the alkenyl group having 2 to 10 carbon atoms include the same groups as those described above.

In the present invention, among these epoxy compounds, the epoxy compounds of the formulae (A3) and (A4) are preferable from the viewpoint of accurately controlling the molecular weight of the resulting polymer, and in particular, those having the following forms can be more suitably used.

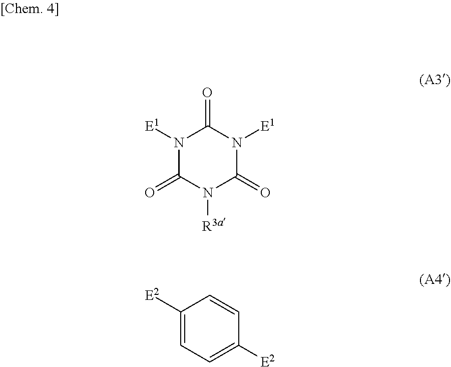

In the formula. E¹ and E² are the same as described above, R^{3a′} represents a hydrogen atom, an alkyl group having 1 to 10 carbon atoms and optionally interrupted by an oxygen atom or a sulfur atom, an alkenyl group having 2 to 10 carbon atoms and optionally interrupted by an oxygen atom or a sulfur atom, an alkynyl group having 2 to 10 carbon atoms optionally interrupted by an oxygen atom or a sulfur atom, a benzyl group, or a phenyl group, and the phenyl group is optionally substituted with at least one monovalent group selected from an alkyl group having 1 to 6 carbon atoms, a halogen atom, an alkoxy group having 1 to 6 carbon atoms, a nitro group, a cyano group, and an alkylthio group having 1 to 6 carbon atoms.

Specific examples of the epoxy compounds of the above formulae (A1) to (A9) include, but are not limited to, the following compounds.

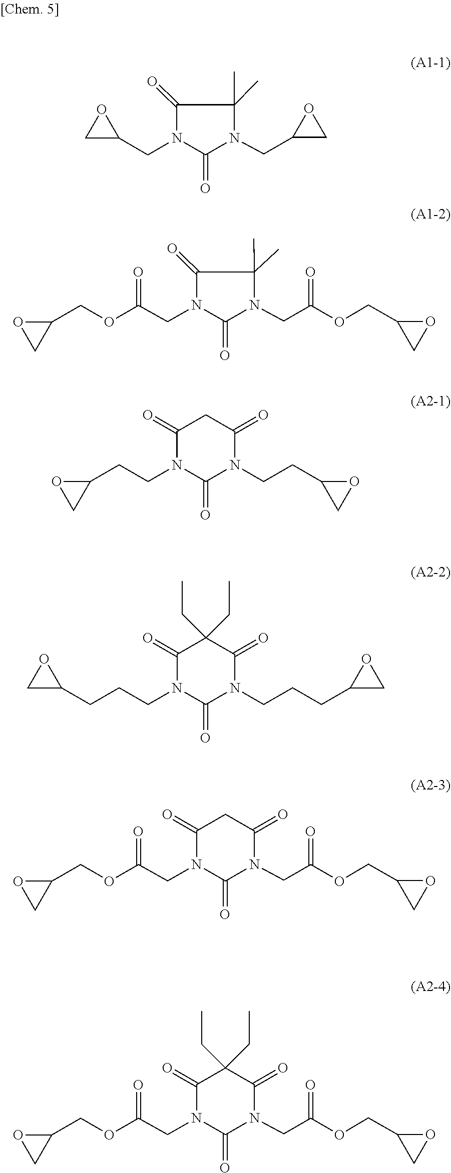 [SMILES: CC1(C)C(=O)N(CC2CO2)C(=O)N1CC1CO1 ; CC1(C)C(=O)N(CC(=O)OCC2CO2)C(=O)N1CCC(=O)OCC1CO1 ; O=C1CC(=O)N(CCC2CO2)C(=O)N1CCC1CO1 ; CCC1(CC)C(=O)N(CCCC2CO2)C(=O)N(CCCC2CO2)C1=O ; O=C(CCN1C(=O)CC(=O)N(CC(=O)OCC2CO2)C1=O)OCC1CO1 ; CCC1(CC)C(=O)N(CCC(=O)OCC2CO2)C(=O)N(CC(=O)OCC2CO2)C1=O]

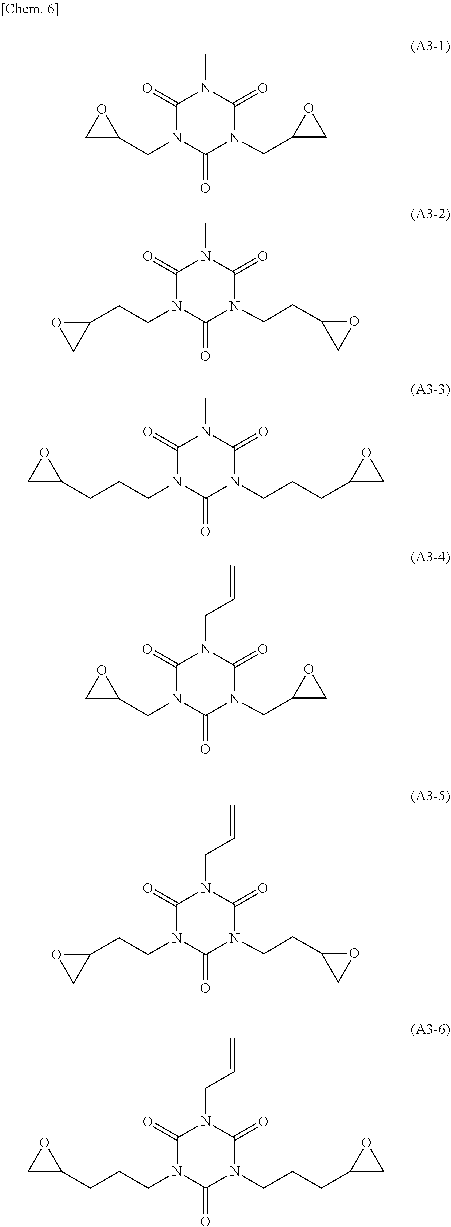

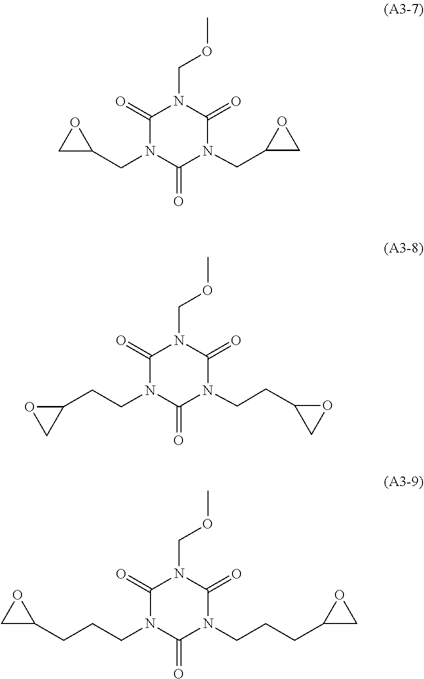 [SMILES: COCn1c(=O)n(CC2CO2)c(=O)n(CC2CO2)c1=O ; COCn1c(=O)n(CCC2CO2)c(=O)n(CCC2CO2)c1=O ; COCn1c(=O)n(CCCC2CO2)c(=O)n(CCCC2CO2)c1=O]

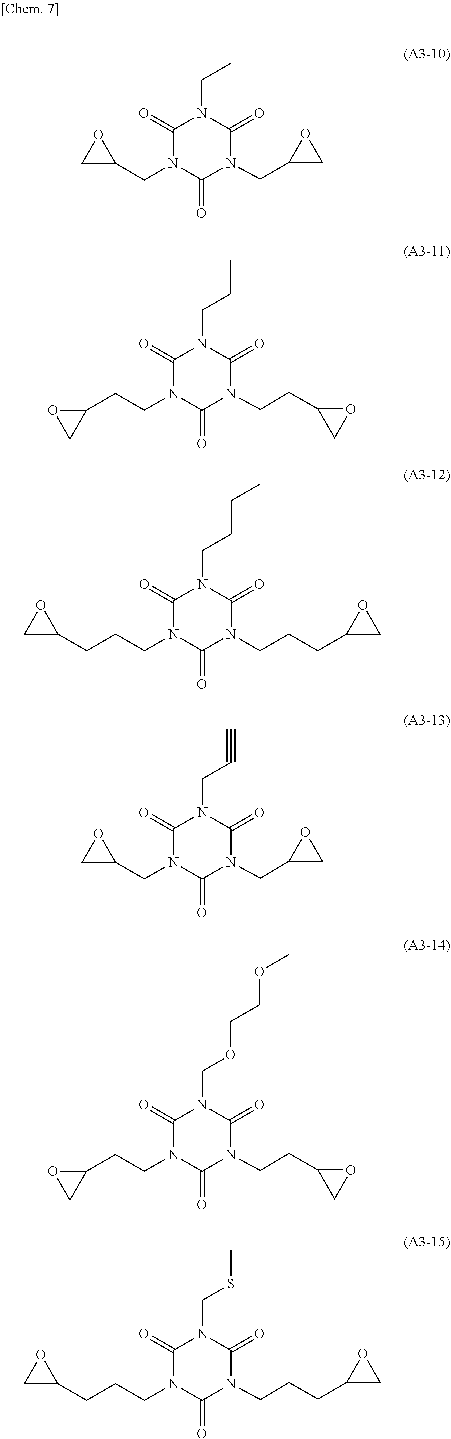 [SMILES: CCn1c(=O)n(CC2CO2)c(=O)n(CC2CO2)c1=O ; CCCn1c(=O)n(CCC2CO2)c(=O)n(CCC2CO2)c1=O ; CCCCn1c(=O)n(CCCC2CO2)c(=O)n(CCCC2CO2)c1=O ; C#CCn1c(=O)n(CC2CO2)c(=O)n(CC2CO2)c1=O ; COCCOCn1c(=O)n(CCC2CO2)c(=O)n(CCC2CO2)c1=O ; CSCn1c(=O)n(CCCC2CO2)c(=O)n(CCCC2CO2)c1=O]

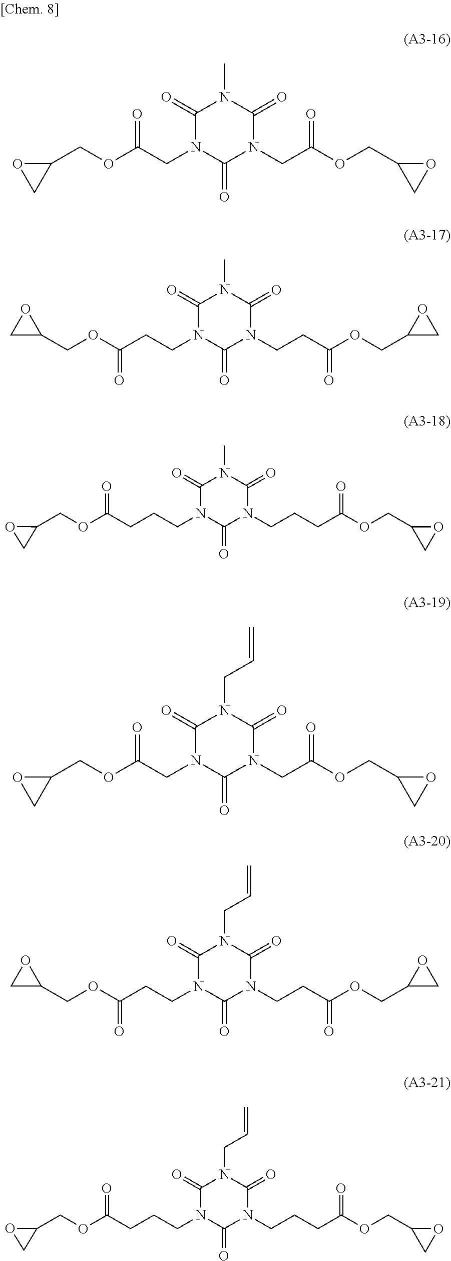 [SMILES: Cn1c(=O)n(CC(=O)OCC2CO2)c(=O)n(CC(=O)OCC2CO2)c1=O ; Cn1c(=O)n(CCC(=O)OCC2CO2)c(=O)n(CCC(=O)OCC2CO2)c1=O ; Cn1c(=O)n(CCCC(=O)OCC2CO2)c(=O)n(CCCC(=O)OCC2CO2)c1=O ; C=CCn1c(=O)n(CC(=O)OCC2CO2)c(=O)n(CC(=O)OCC2CO2)c1=O ; C=CCn1c(=O)n(CCC(=O)OCC2CO2)c(=O)n(CCC(=O)OCC2CO2)c1=O ; C=CCn1c(=O)n(CCCC(=O)OCC2CO2)c(=O)n(CCCC(=O)OCC2CO2)c1=O]

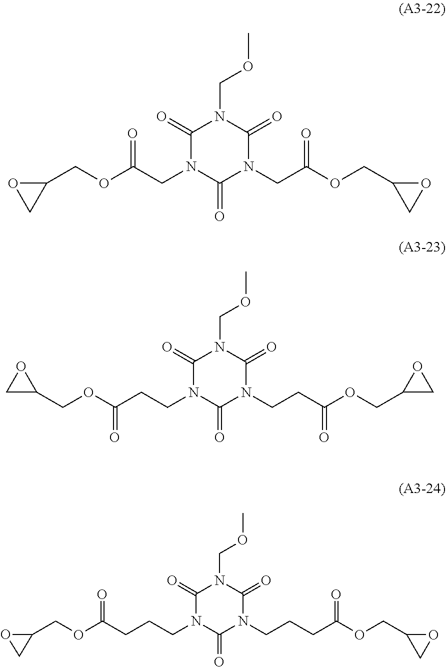 [SMILES: COCn1c(=O)n(CC(=O)OCC2CO2)c(=O)n(CC(=O)OCC2CO2)c1=O ; COCn1c(=O)n(CCC(=O)OCC2CO2)c(=O)n(CCC(=O)OCC2CO2)c1=O ; COCn1c(=O)n(CCCC(=O)OCC2CO2)c(=O)n(CCCC(=O)OCC2CO2)c1=O]

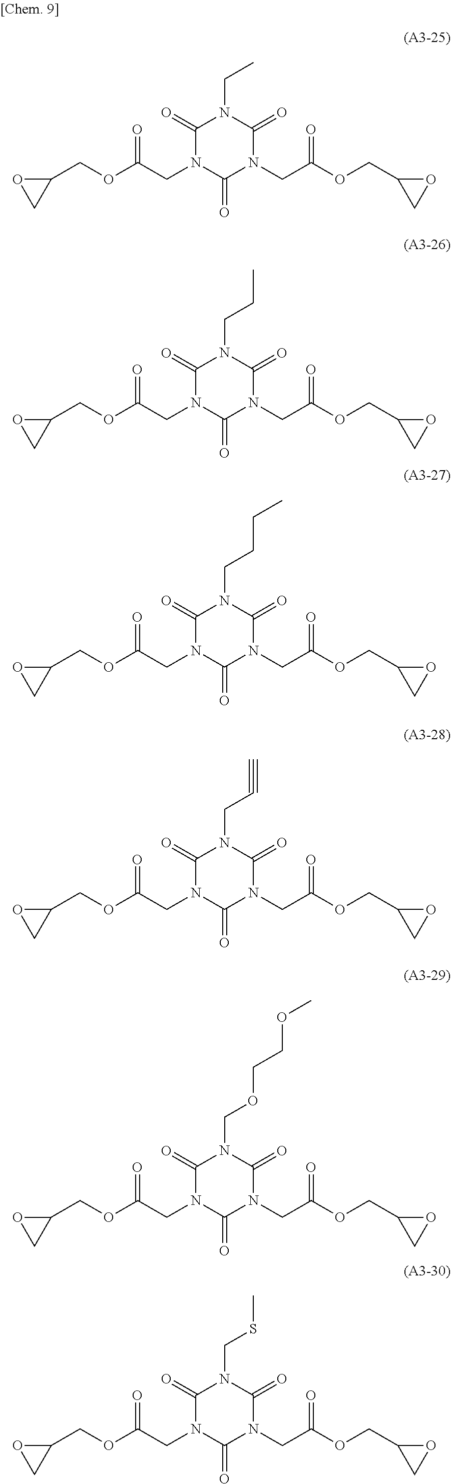 [SMILES: CCn1c(=O)n(CC(=O)OCC2CO2)c(=O)n(CC(=O)OCC2CO2)c1=O ; CCCn1c(=O)n(CC(=O)OCC2CO2)c(=O)n(CC(=O)OCC2CO2)c1=O ; CCCCn1c(=O)n(CC(=O)OCC2CO2)c(=O)n(CC(=O)OCC2CO2)c1=O ; C#CCn1c(=O)n(CC(=O)OCC2CO2)c(=O)n(CC(=O)OCC2CO2)c1=O ; COCCOCn1c(=O)n(CC(=O)OCC2CO2)c(=O)n(CC(=O)OCC2CO2)c1=O ; CSCn1c(=O)n(CC(=O)OCC2CO2)c(=O)n(CC(=O)OCC2CO2)c1=O]

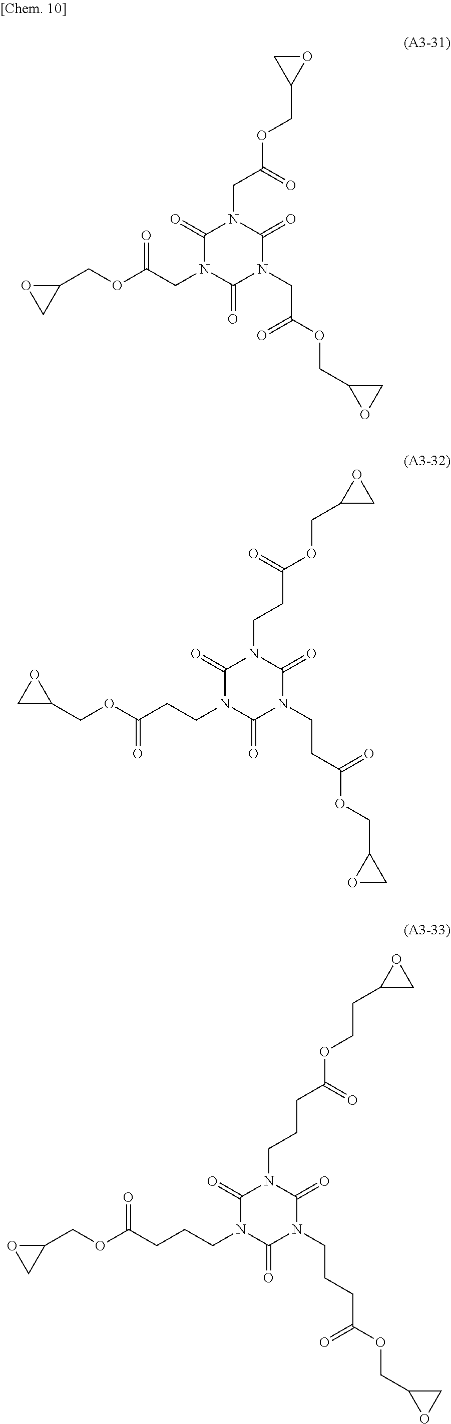 [SMILES: O=C(Cn1c(=O)n(CC(=O)OCC2CO2)c(=O)n(CC(=O)OCC2CO2)c1=O)OCC1CO1 ; O=C(CCn1c(=O)n(CCC(=O)OCC2CO2)c(=O)n(CCC(=O)OCC2CO2)c1=O)OCC1CO1 ; O=C(CCCn1c(=O)n(CCCC(=O)OCC2CO2)c(=O)n(CCCC(=O)OCC2CO2)c1=O)OCCC1CO1]

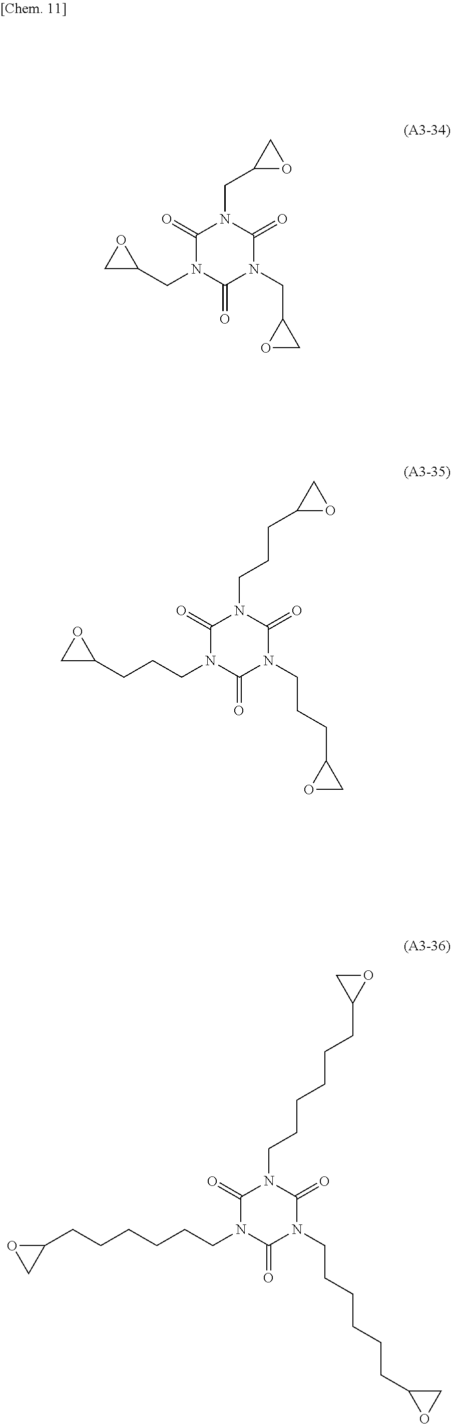 [SMILES: O=c1n(CC2CO2)c(=O)n(CC2CO2)c(=O)n1CC1CO1 ; O=c1n(CCCC2CO2)c(=O)n(CCCC2CO2)c(=O)n1CCCC1CO1 ; O=c1n(CCCCCCC2CO2)c(=O)n(CCCCCCC2CO2)c(=O)n1CCCCCCC1CO1]

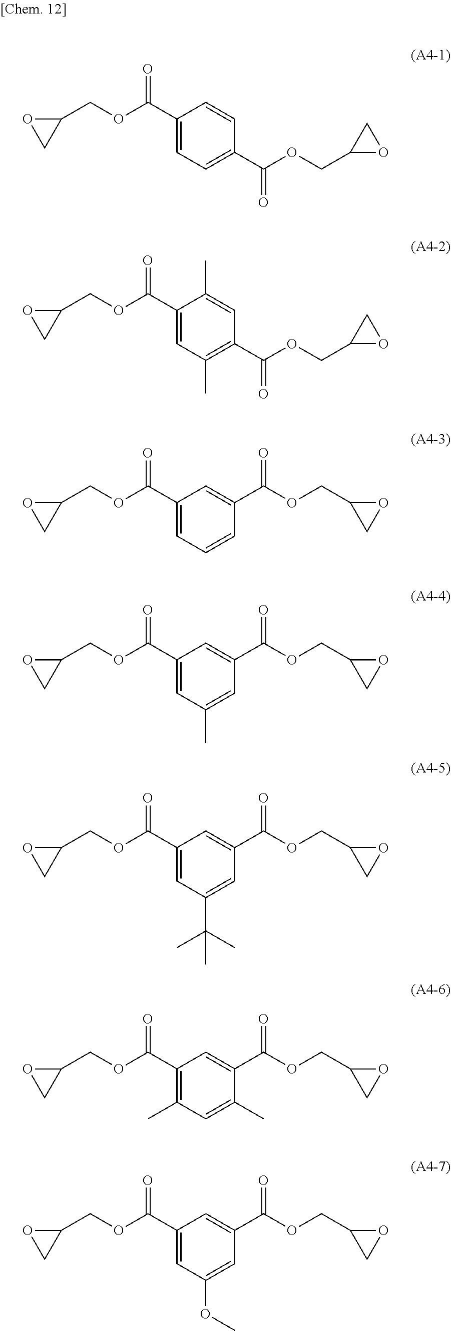

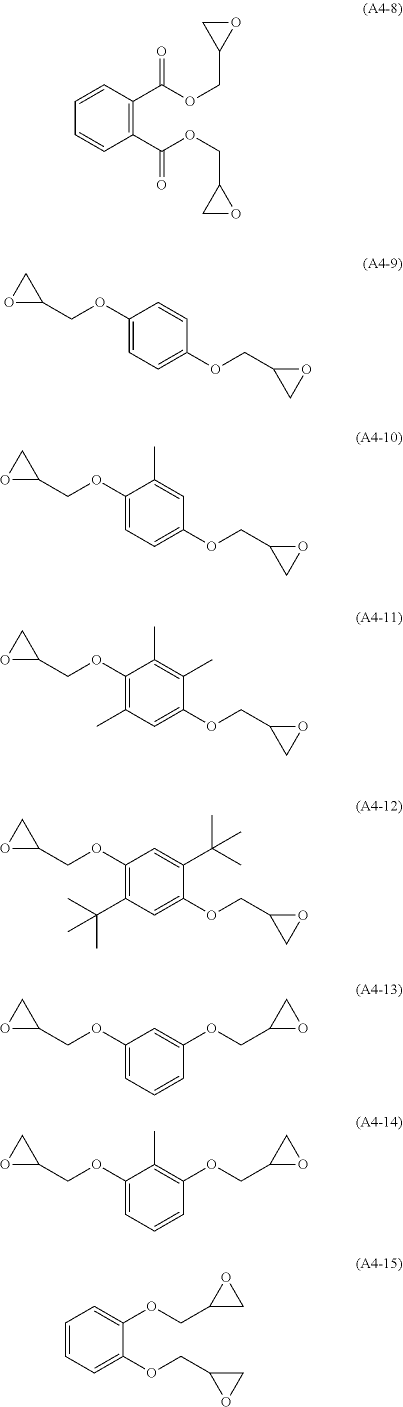

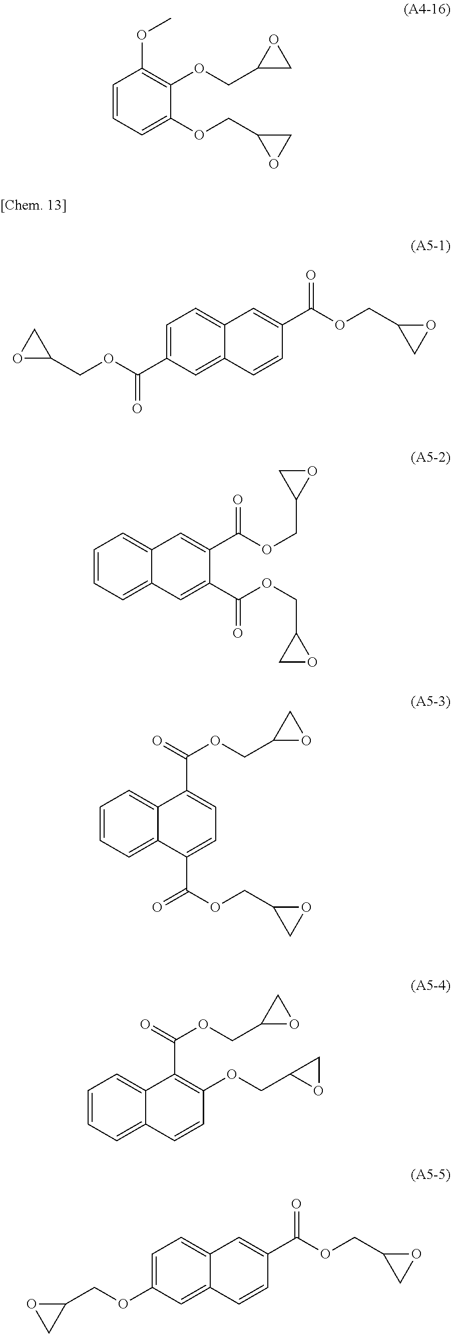 [SMILES: COc1cccc(OCC2CO2)c1OCC1CO1 ; O=C(OCC1CO1)c1ccc2cc(C(=O)OCC3CO3)ccc2c1 ; O=C(OCC1CO1)c1cc2ccccc2cc1C(=O)OCC1CO1 ; O=C(OCC1CO1)c1ccc(C(=O)OCC2CO2)c2ccccc12 ; O=C(OCC1CO1)c1c(OCC2CO2)ccc2ccccc12 ; O=C(OCC1CO1)c1ccc2cc(OCC3CO3)ccc2c1]

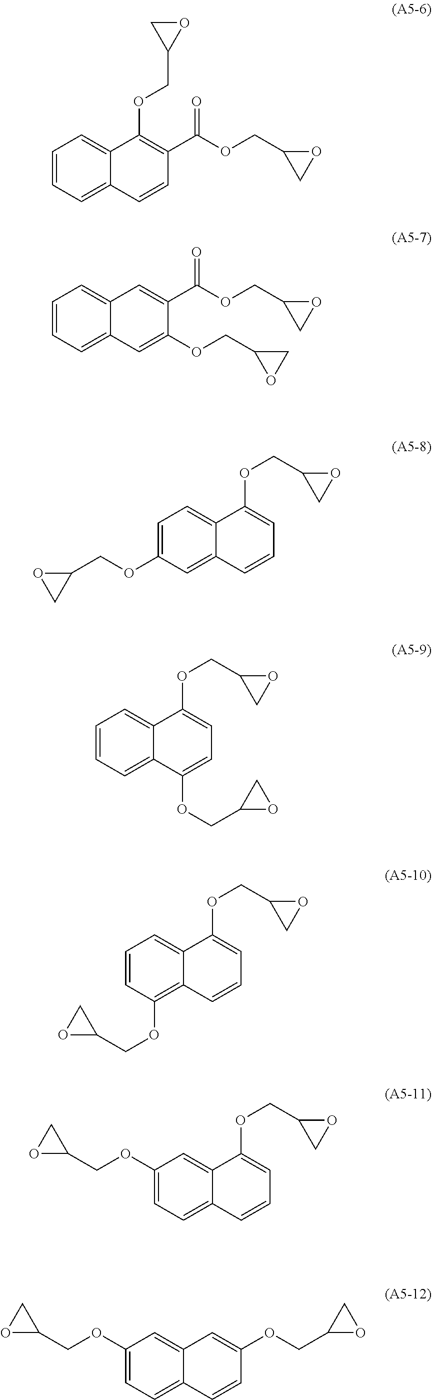

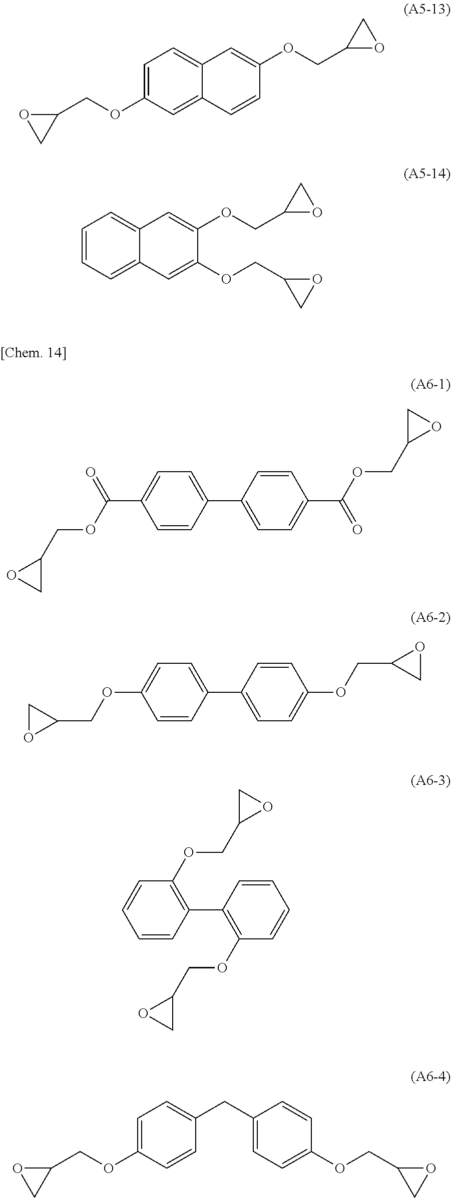 [SMILES: c1cc2cc(OCC3CO3)ccc2cc1OCC1CO1 ; c1ccc2cc(OCC3CO3)c(OCC3CO3)cc2c1 ; O=C(OCC1CO1)c1ccc(-c2ccc(C(=O)OCC3CO3)cc2)cc1 ; c1cc(-c2ccc(OCC3CO3)cc2)ccc1OCC1CO1 ; c1ccc(-c2ccccc2OCC2CO2)c(OCC2CO2)c1 ; c1cc(OCC2CO2)ccc1Cc1ccc(OCC2CO2)cc1]

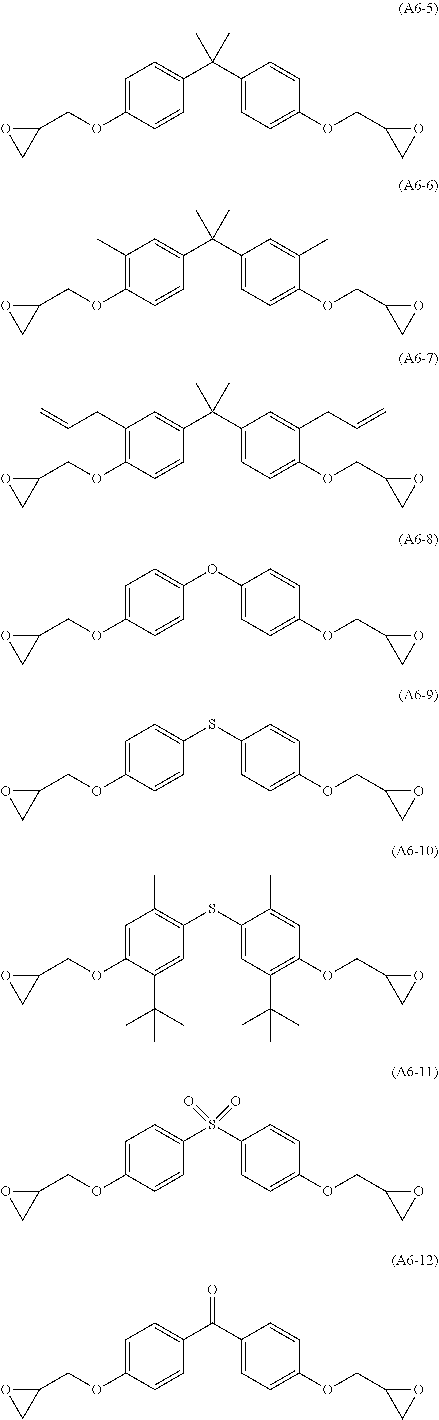

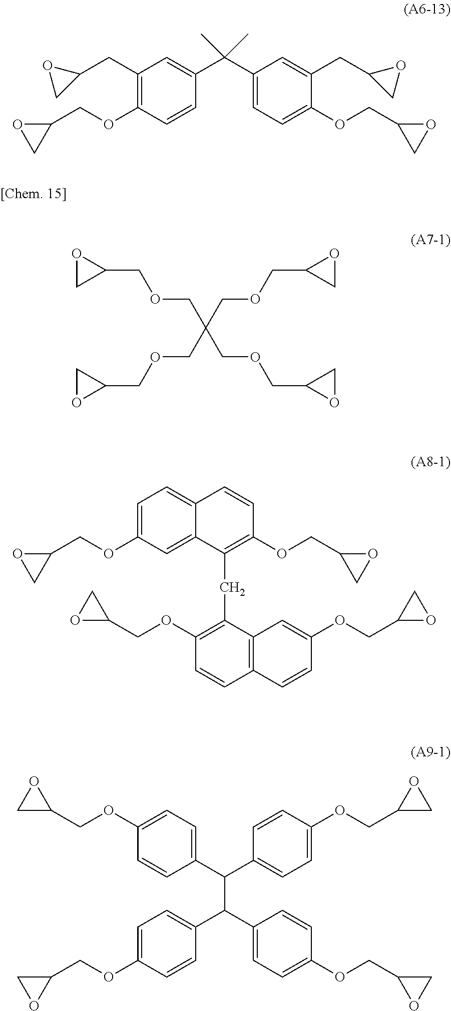 [SMILES: CC(C)(c1ccc(OCC2CO2)c(CC2CO2)c1)c1ccc(OCC2CO2)c(CC2CO2)c1 ; C(OCC(COCC1CO1)(COCC1CO1)COCC1CO1)C1CO1 ; c1cc2ccc(OCC3CO3)c(Cc3c(OCC4CO4)ccc4ccc(OCC5CO5)cc34)c2cc1OCC1CO1 ; c1cc(C(c2ccc(OCC3CO3)cc2)C(c2ccc(OCC3CO3)cc2)c2ccc(OCC3CO3)cc2)ccc1OCC1CO1]

Examples of the polymer having an epoxy group include polymers having repeating units of the following formulae (A10-1) to (A10-12).

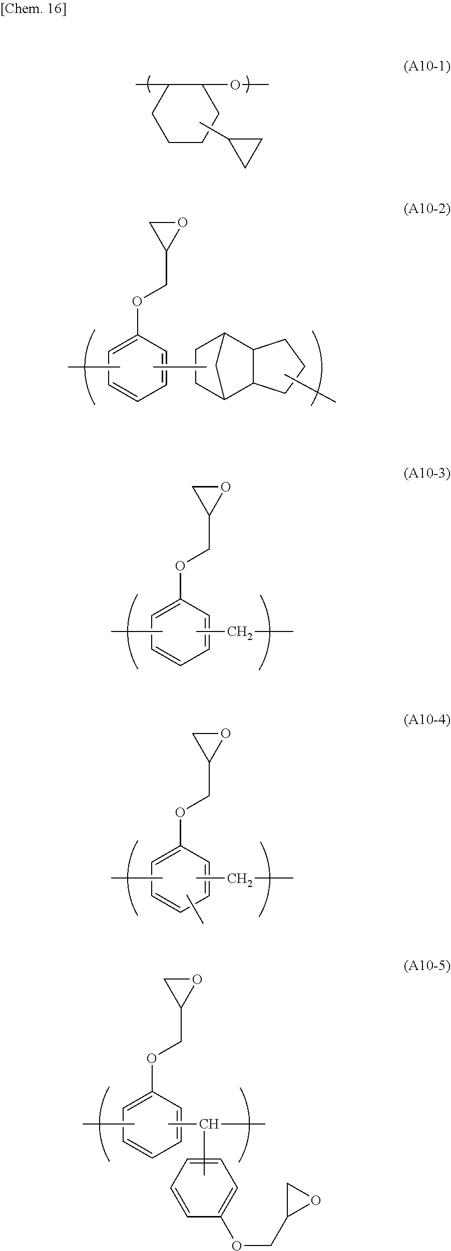

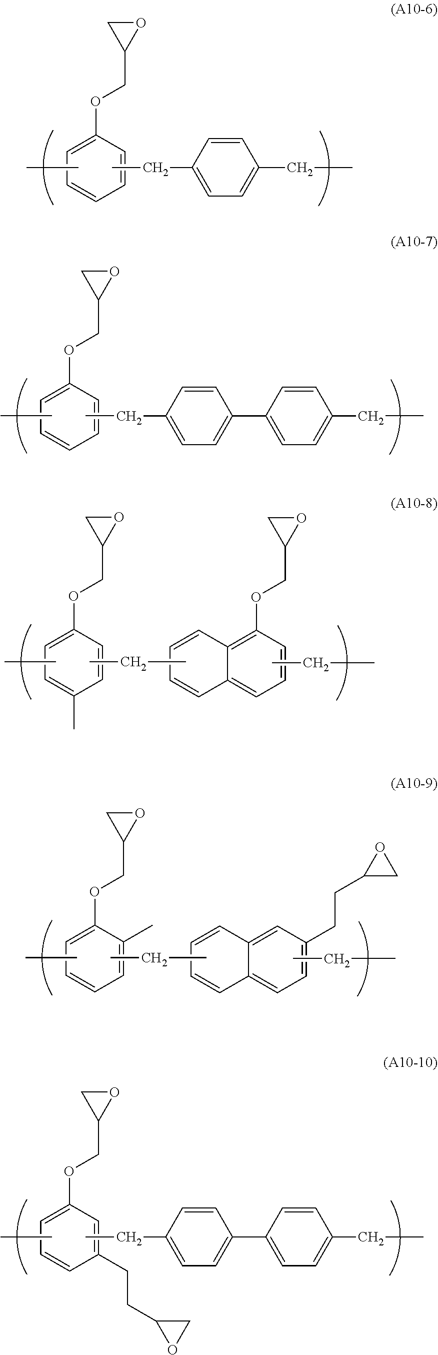

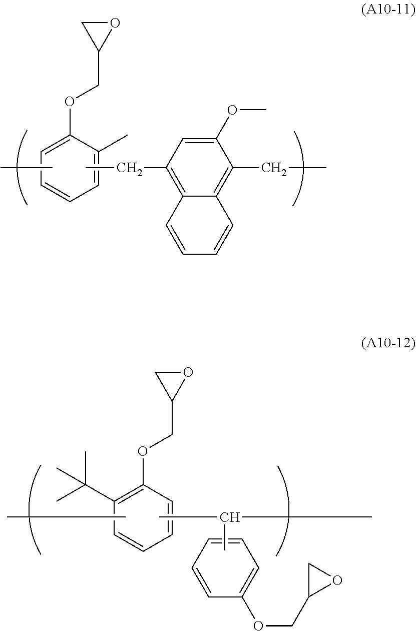

In the present invention, specific examples of the component (A) may also include epoxy compounds of the following formulae (A11-1) to (A11-2).

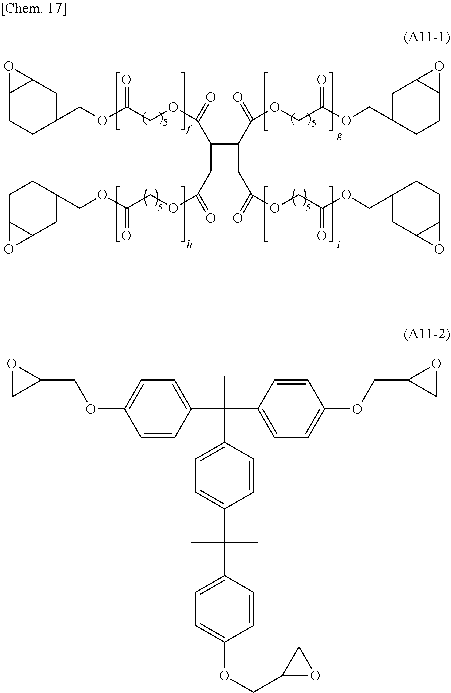

In the formula (A 11-1), each of f, g, h and i is 0 or 1, where f+g+h+i is 1.

The (B) reactive compound having two or more functional groups reactive with an epoxy group in the molecule is preferably a compound having two or more, more preferably two or three functional groups reactive with an epoxy group in the molecule in view of accurately controlling the weight average molecular weight of the resulting polymer.

Examples of the functional group of the component (B) include a hydroxyl group, a formyl group, a carboxy group, an amino group, an imino group, an azo group, an azi group, a thiol group, a sulfo group, an amide group, an imide group, a thiocarboxy group, a dithiocarboxy group, a phosphate group, a phosphite group, a phosphonate group, a phosphonite group, a phosphinate group, a phosphinite group, a phosphine group, an acid anhydride or an acid chloride. In the present invention, a hydroxyl group, a carboxy group, an amino group, an imide group and an amide group are preferable.

Specific examples of the component (B) include, but are not limited to, the following compounds.

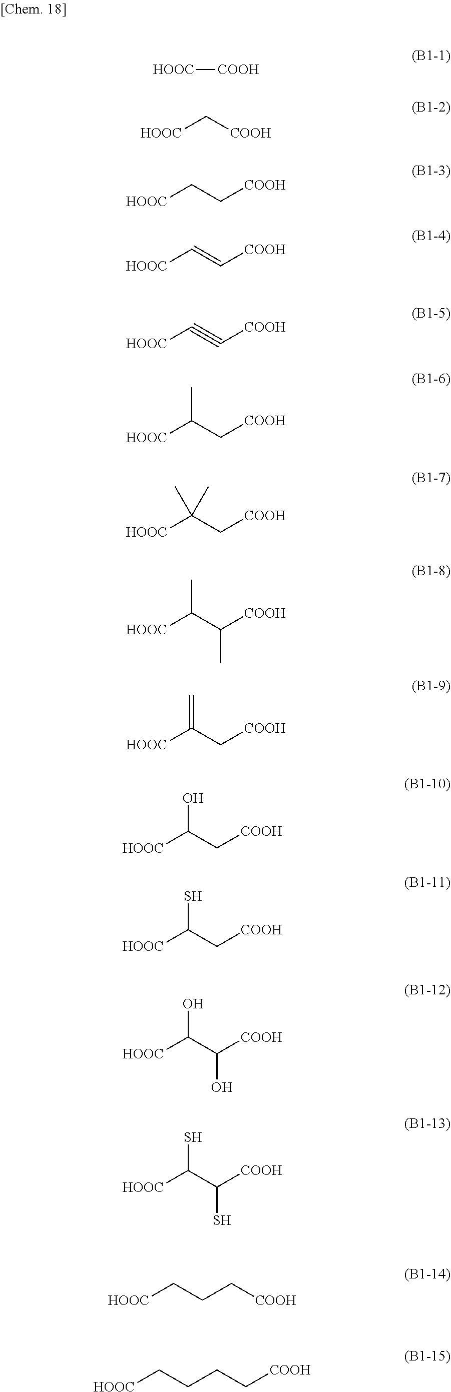

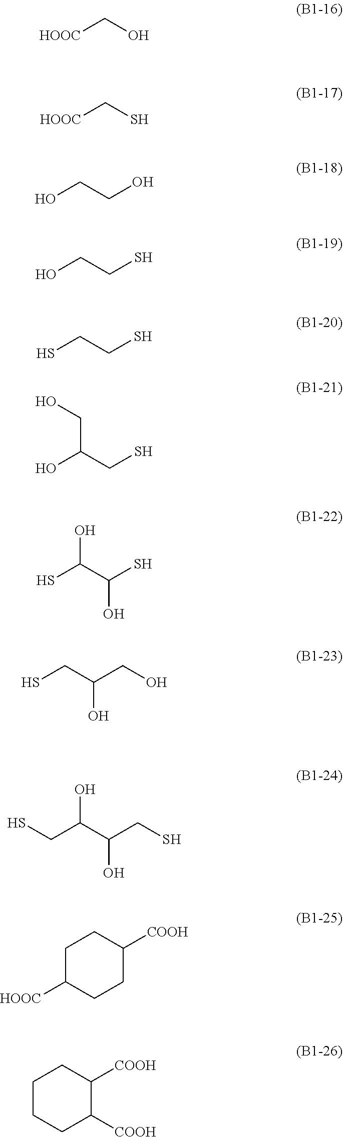

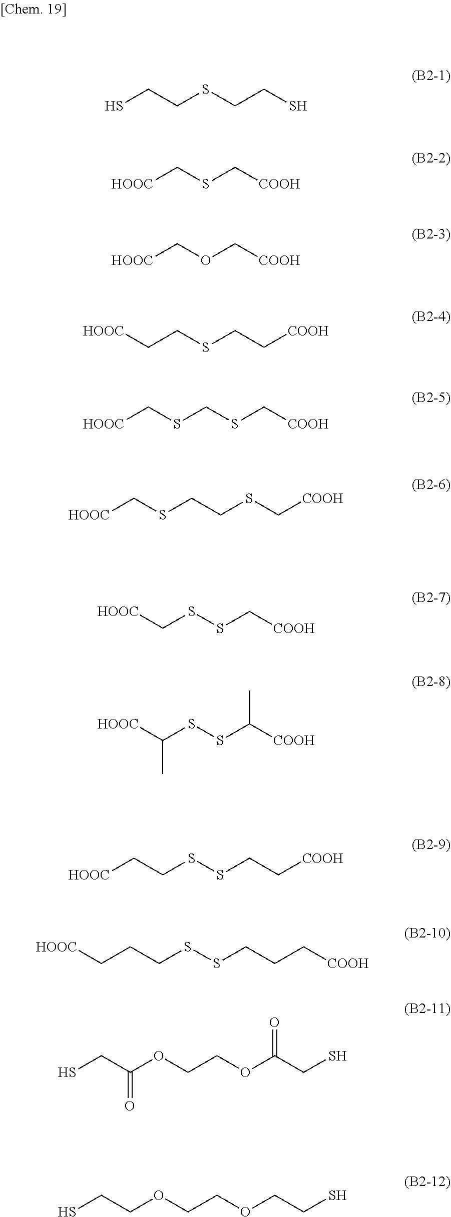

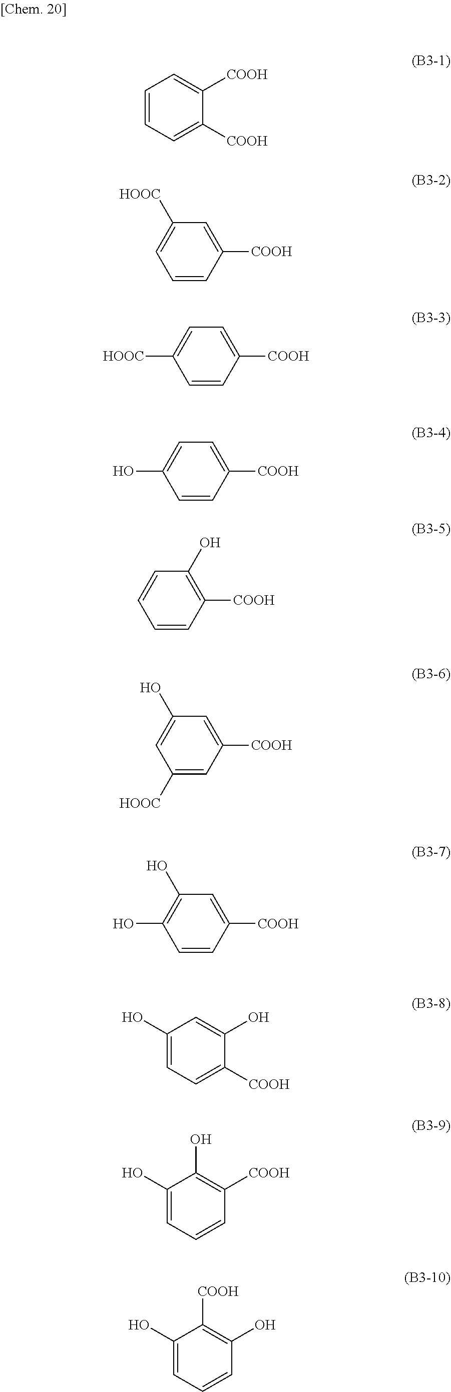

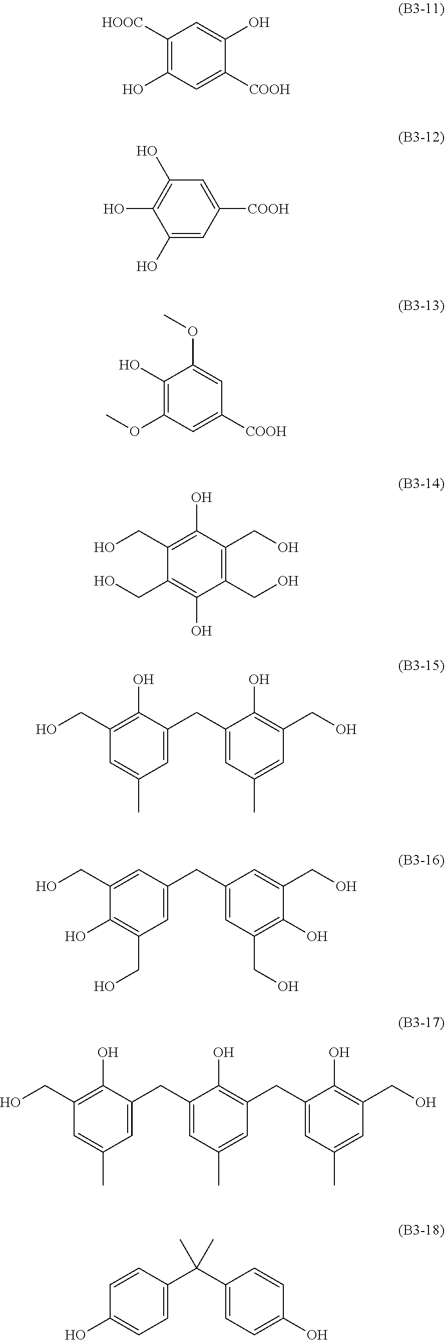

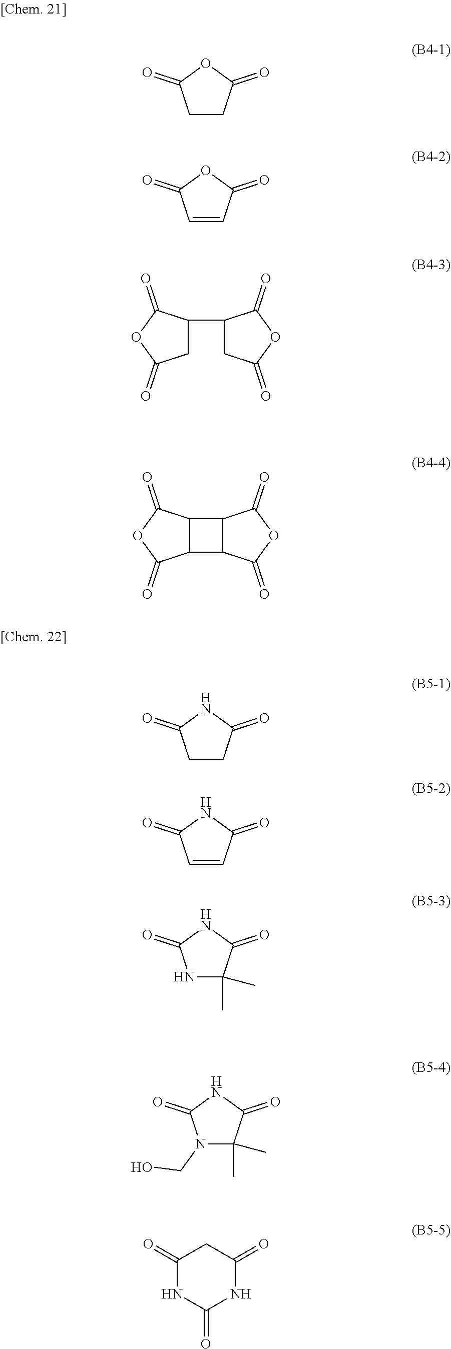

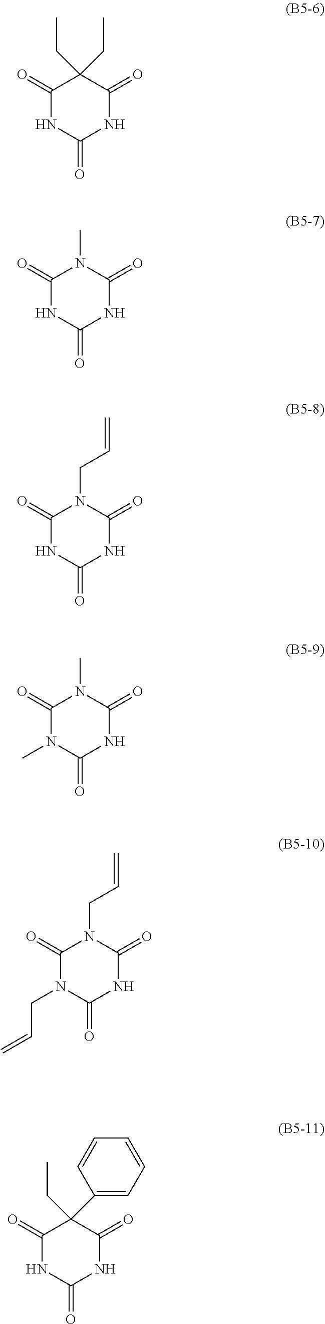

The compounding amount of the component (B) is set as an equivalent ratio of epoxy groups of the component (A) to functional groups of the component (B). In the 10 present invention, the equivalent ratio is preferably 0.1:1.0 to 1.0:0.1 in terms of (A):(B), more preferably 0.5:1.0 to 1.0:0.5 in terms of (A):(B) in terms of accurately controlling the weight average molecular weight of the resulting polymer.

The (C) polymerization catalyst is a component which is added as a catalyst for the reaction between of component (A) with the component (B) described above. In the present invention, by using the component (C) in combination with the co-catalyst (D) described later, the molecular weight of a polymer in the reaction system can be controlled to an appropriate molecular weight and stabilized without continuously increasing the molecular weight of the polymer.

In the present invention, the component (C) is preferably an onium salt having one or more quaternary Group 15 element structures in view of accurately controlling the weight average molecular weight of the resulting polymer.

The number of quaternary Group 15 element structures is preferably 1 or 2, more preferably 1.

Examples of the Group 15 element include nitrogen, phosphorus, arsenic, antimony and bismuth, and nitrogen and phosphorus are preferable.

Examples of the substituent in the Group 15 element structure include alkyl groups having 1 to 20 carbon atoms, aryl groups having 6 to 20 carbon atoms, and aralkyl groups having 7 to 20 carbon atoms.

Examples of the alkyl group having 1 to 20 carbon atoms include n-undecyl, n-dodecyl, n-tridecyl, n-tetradecyl, n-pentadecyl, n-hexadecyl, n-heptadecyl, n-octadecyl, n-nonadecyl and n-eicosanyl groups in addition to the groups exemplified for the alkyl group having 1 to 10 carbon atoms. In the present invention, alkyl groups having 1 to 10 carbon atoms are preferable, and alkyl groups having 1 to 8 carbon atoms are more preferable.

Examples of the aryl group of 6 to 20 carbon atoms include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group and a 9-phenanthryl group. In the present invention, a phenyl group is preferable.

Specific examples of the aralkyl group having 7 to 20 carbon atoms include a benzyl group, a p-methylphenylmethyl group, an m-methylphenylmethyl group, an o-ethylphenylmethyl group, an m-ethylphenylmethyl group, a p-ethylphenylmethyl group, a 2-propylphenylmethyl group, a 4-isopropylphenylmethyl group, a 4-isobutylphenylmethyl group and an α-naphthylmethyl group. In the present invention, a benzyl group is preferable.

Examples of the counter anion in the onium salt include halide ions, nitrate ions, sulfate ions, acetate ions, formate ions, hydroxide ions, and sulfonate ions having an alkyl group having 1 to 20 carbon atoms or an aryl group having 6 to 20 carbon atoms. Examples of the halide ion include fluoride ions, chloride ions, bromide ions, and iodide ions. In the present invention, halide ions are preferable.

In the sulfonate ion, the alkyl group having 1 to 20 carbon atoms and the aryl group having 6 to 20 carbon atoms are the same as those described above.

Specific examples of the sulfonate ion include methanesulfonic acid, p-toluenesulfonic acid and benzenesulfonic acid.

Examples of the preferred form of the component (C) include onium salts of the following formula (Cl).

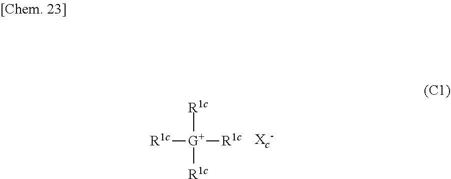

wherein G represents a Group 15 element, R^{1c}s each independently represent an alkyl group having 1 to 20 carbon atoms, an aryl group having 6 to 20 carbon atoms, or an aralkyl group having 7 to 20 carbon atoms, and X_{c}⁻ represents a halide ion, a nitrate ion, a sulfate ion, an acetate ion, a formate ion, a hydroxide ion, or a sulfonate ion having an alkyl group having 1 to 20 carbon atoms or an aryl group having 6 to 20 carbon atoms.

The Group 15 element, the alkyl group having 1 to 20 carbon atoms, the aryl group having 6 to 20 carbon atoms, the aralkyl group having 7 to 20 carbon atoms, the halide ion, and the sulfonate ion are the same as described above.

In the present invention, as the component (C), quaternary ammonium salts and quaternary phosphonium salts are preferable, and quaternary phosphonium salts are more preferable.

Examples of the quaternary ammonium salt include tetramethylammonium fluoride, tetramethylammonium chloride, tetramethylammonium bromide, tetramethylammonium nitrate, tetramethylammonium sulfate, tetramethylammonium acetate, tetraethylammonium chloride, tetraethylammonium bromide, tetrapropylammonium chloride, tetrapropylammonium bromide, tetrabutylammonium fluoride, tetrabutylammonium chloride, tetrabutylammonium bromide, benzyltrimethylammonium chloride, phenyltrimethylammonium chloride, benzyltriethylammonium chloride, methyltributylammonium chloride, benzyltributylammonium chloride and methyltrioctylammonium chloride.

Examples of the quaternary phosphonium salt include methyltriphenylphosphonium bromide, ethyltriphenylphosphonium bromide, butyltriphenylphosphonium bromide, hexyltriphenylphosphonium bromide, tetrabutylphosphonium bromide, benzyltriphenylphosphonium bromide, methyltriphenylphosphonium chloride, ethyltriphenylphosphonium chloride, butyltriphenylphosphonium chloride, hexyltriphenylphosphonium chloride, tetrabutylphosphonium chloride, benzyltriphenylphosphonium chloride, methyltriphenylphosphonium iodide, ethyltriphenylphosphonium iodide, butyltriphenylphosphonium iodide, hexyltriphenylphosphonium iodide, tetrabutylphosphonium iodide, and benzyltriphenylphosphonium iodide. In the present invention, ethyltriphenylphosphonium bromide and tetrabutylphosphonium bromide can be suitably used.

The compounding amount of the component (C) is not particularly limited as long as it is an amount that allows the reaction to proceed, and in view of appropriately controlling the polymerization reaction of the polymer, the compounding amount of the component (C) is preferably 0.0001 to 0.5 mol, more preferably 0.0005 to 0.1 mol, still more preferably 0.001 to 0.05 mol per 1 mol of the component (A).

The (D) co-catalyst is a component used in combination with the component (C), and by using the co-catalyst in combination with the component (C), the molecular weight of a polymer in the reaction system can be controlled to an appropriate molecular weight and stabilized without continuously increasing the molecular weight of the polymer.

In the present invention, the component (D) is preferably a compound having a primary to tertiary Group 15 element structure or a heteroaryl compound containing a Group 15 element in the aromatic ring, more preferably a compound having a tertiary Group 15 element structure or a heteroaryl compound containing a Group 15 element in the aromatic ring, in view of accurately controlling the weight average molecular weight of the resulting polymer.

Examples of the Group 15 element include nitrogen, phosphorus, arsenic, antimony and bismuth, and nitrogen and phosphorus are preferable.

Examples of the substituent in the Group 15 element structure include alkyl groups having 1 to 20 carbon atoms, aryl groups having 6 to 20 carbon atoms, and aralkyl groups having 7 to 20 carbon atoms.

Examples of the alkyl group having 1 to 20 carbon atoms include the same groups as those exemplified above. In the present invention, alkyl groups having 1 to 6 carbon atoms are preferable, and alkyl groups having 1 to 4 carbon atoms are more preferable.

Examples of the aryl group having 6 to 20 carbon atoms include the same groups as those exemplified above. In the present invention, a phenyl group is preferable.

Examples of the aralkyl group having 7 to 20 carbon atoms include the same groups as those exemplified above. In the present invention, a benzyl group is preferable.

Preferred specific examples of the component (D) include compounds of the following formula (D1) or (D2).

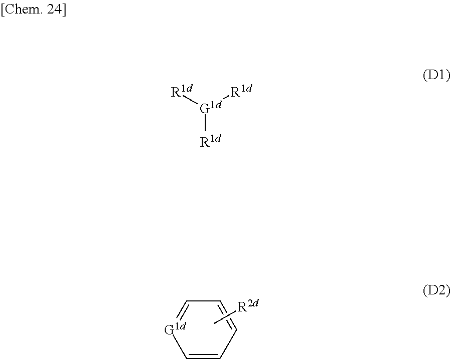

wherein G^{1d} represents a Group 15 element. R^{1d}s each independently represent an alkyl group having 1 to 20 carbon atoms, an aryl group having 6 to 20 carbon atoms, or an aralkyl group having 7 to 20 carbon atoms, and R^{2d} represents a hydrogen atom, or a dialkylamino group in which each alkyl group is independently an alkyl group having 1 to 12 carbon atoms.

In (D1), examples of the alkyl group having 1 to 20 carbon atoms include the same groups as those exemplified above. In the present invention, alkyl groups having 1 to 10 carbon atoms are preferable, and alkyl groups having 1 to 6 carbon atoms are more preferable.

Examples of the aryl group having 6 to 20 carbon atoms include the same groups as those exemplified above. In the present invention, a phenyl group is preferable.

Examples of the aralkyl group having 7 to 20 carbon atoms include the same groups as those exemplified above. In the present invention, a benzyl group is preferable.

In the formula (D2), examples of the alkyl group having 1 to 12 carbon atoms include the same groups as the alkyl groups having 1 to 12 carbon atoms as presented in the above-described alkyl groups having 1 to 20 carbon atoms. In the present invention, alkyl groups having 1 to 6 carbon atoms are preferable, and alkyl groups having 1 to 4 carbon atoms are more preferable.

Preferred embodiments of the compound represented by the formula (D2) include those represented by the following formula (D2′).

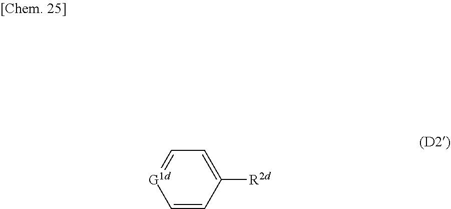

wherein G^{1d} and R^{2d} represent the same meaning as described above.

Preferred specific examples of the component (D) include pyridine, N,N-dimethyl-4-aminopyridine, tributylphosphine and triphenylphosphine.

The compounding amount of the component (D) is not particularly limited as long as it is an amount that allows the reaction to proceed, and in view of appropriately controlling the polymerization reaction of the polymer, the compounding amount of the component (D) is preferably 0.0001 to 0.5 mol, more preferably 0.0005 to 0.2 mol, still more preferably 0.001 to 0.1 mol per 1 mol of the component (A).

The total amount of the component (C) and the component (D) is preferably 0.0002 to 0.5 mol, more preferably 0.001 to 0.2 mol per 1 mol of the component (A).

The compounding ratio (molar ratio) of the (C) polymerization catalyst to the (D) co-catalyst is preferably 0.1:1.0 to 1.0:0.1, more preferably 0.3:1.0 to 1.0:0.3 in view of accurately controlling the weight average molecular weight of the resulting polymer.

In the production method of the present invention, a known organic solvent can be used.

The organic solvent can be used without particular limitation as long as it can dissolve the compound or the reaction product thereof and does not affect the polymerization reaction. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone. N,N-dimethylformamide and N,N-dimethylacetamide. In the present invention, among these solvents, propylene glycol monomethyl ether, propylene glycol monomethyl ether acetate, ethyl lactate, butyl lactate and cyclohexanone are preferable, and propylene glycol monomethyl ether and propylene glycol monomethyl ether acetate are more preferable. These solvents can be used singly or in combination of two or more thereof.

The amount of the organic solvent used is preferably 0.1 to 100 parts by weight, more preferably 0.5 to 20 parts by weight per 1.0 part by weight of the component (A) in view of accurately controlling the weight average molecular weight of the resulting polymer.

The reaction temperature (internal temperature) is preferably 25 to 200° C., more preferably 50 to 150° C., still more preferably 80 to 150° C. in view of allowing the reaction to efficiently proceed and accurately controlling the weight average molecular weight of the resulting polymer. Reflux may be performed during heating.

The reaction time depends on the reaction temperature and the reactivity of the raw material substance, and therefore cannot be uniquely defined. The reaction time is normally about 1 to 30 hours, and is about 1 to 15 hours when the reaction temperature is 100 to 130° C.

The weight average molecular weight Mw of the polymer obtained by the method for producing a polymer according to the present invention is 500 to 100,000, but when a certain period of time elapses after the reaction is started, the molecular weight plateaus, and is thereafter stabilized near an intended molecular weight (within about f 300).

In the present invention, the weight average molecular weight Mw is a value in terms of polystyrene measured by gel permeation chromatography (GPC).

Thus, by adopting the method for producing a polymer according to the present invention, the weight average molecular weight of the resulting polymer can be accurately controlled, and a polymer having an intended weight average molecular weight can be reproducibly produced.

In addition, the polymer obtained by the production method of the present invention can be applied to, for example, an antireflection film forming composition for lithography, a resist lower layer film forming composition, a resist upper layer film forming composition, a photocurable resin composition, a thermosetting resin composition, a flattened film forming composition, an adhesive agent composition, and other compositions.

For example, when the polymer obtained is used in a resist lower layer film forming composition, the polymer solution after reaction may be appropriately mixed with components such as a crosslinker and a crosslinking catalyst.

### EXAMPLES

Examples and Comparative Examples are given below to more concretely illustrate the present invention, although the present invention is not limited by these Examples. The measuring apparatuses and the abbreviations and structures of raw materials used in Examples are as follows.

### [Measurement of Weight Average Molecular Weight Mw and Polydispersity Mw/Mn]

The weight average molecular weight Mw and the polydispersity Mw/Mn of the polymer were calculated from each peak in a chromatogram obtained by measurement by gel permeation chromatography (GPC) and on the basis of a calibration curve. The measurement conditions are as follows.

### <Measurement Conditions>

Apparatus: HLC-8320 GPC (manufactured by TOSOH CORPORATION)
Column: Shodex [registered trademark] (Showa Denko K.K.)
Eluent: lithium bromide at 10 mM/DMF
Flow rate: 0.6 mL/min
Column temperature: 40° C.

### Detector: RI

Standard sample: polystyrene
(A) Epoxy compound
(a1) Monoallyldiglycidylisocyanuric acid; molecular weight 269.26
(a2) Terephthalic acid diglycidyl ester: molecular weight 278.26

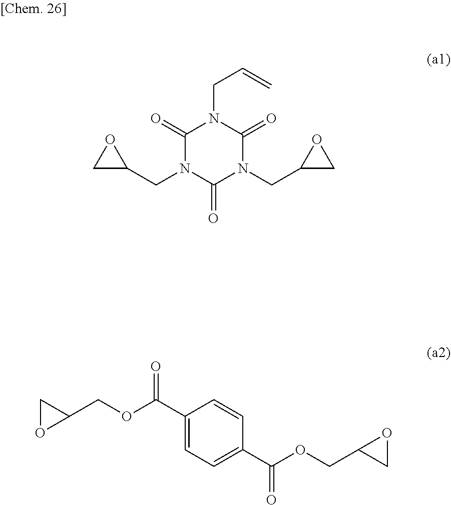 [SMILES: C=CCn1c(=O)n(CC2CO2)c(=O)n(CC2CO2)c1=O ; O=C(OCC1CO1)c1ccc(C(=O)OCC2CO2)cc1]

(B) Reactive compound
(b1) Adipic acid: molecular weight 79.10
(b2) 3,3-dithiopropionic acid: molecular weight 210.26
(b3) Barbital: molecular weight 184.20
(b4) Bisphenol A: molecular weight 228.29

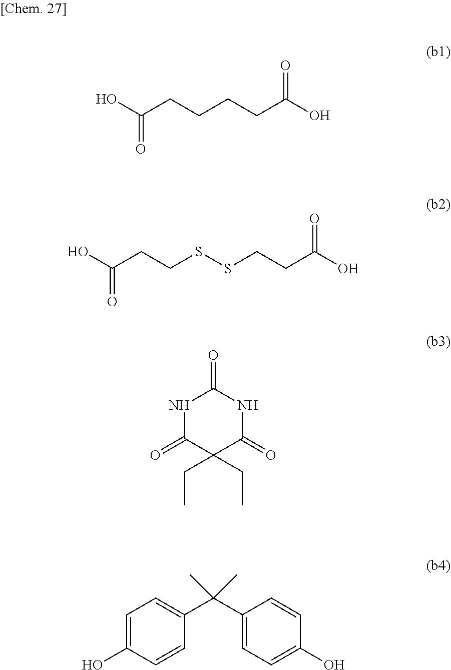 [SMILES: O=C(O)CCCCC(=O)O ; O=C(O)CCSSCCC(=O)O ; CCC1(CC)C(=O)NC(=O)NC1=O ; CC(C)(c1ccc(O)cc1)c1ccc(O)cc1]

(C) Polymerization catalyst
(c1) Ethyltriphenylphosphonium bromide: molecular weight 371.26
(c2) Tetrabutylphosphonium bromide: molecular weight 339.34

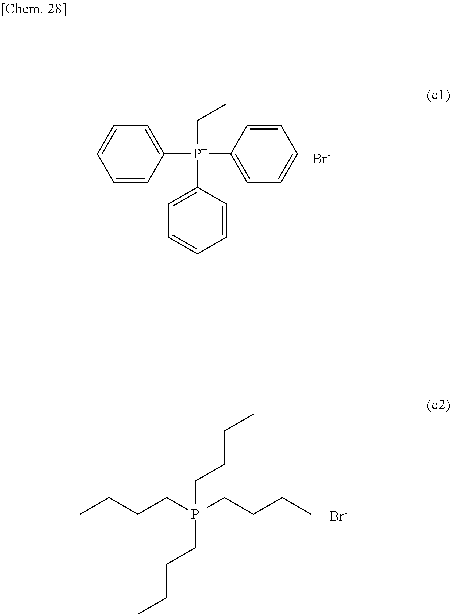 [SMILES: CC[P+](c1ccccc1)(c1ccccc1)c1ccccc1 ; [Br-] ; CCCC[P+](CCCC)(CCCC)CCCC ; [Br-]]

### (D) Co-catalyst

(d1) Pyridine: molecular weight 79.10
(d2) N,N-dimethyl-4-aminopyridine: molecular weight 122.17
(d3) Tributylphosphine: Bu3P, molecular weight: 202.32
(d4) Triphenylphosphine: Ph3P, molecular weight: 262.29

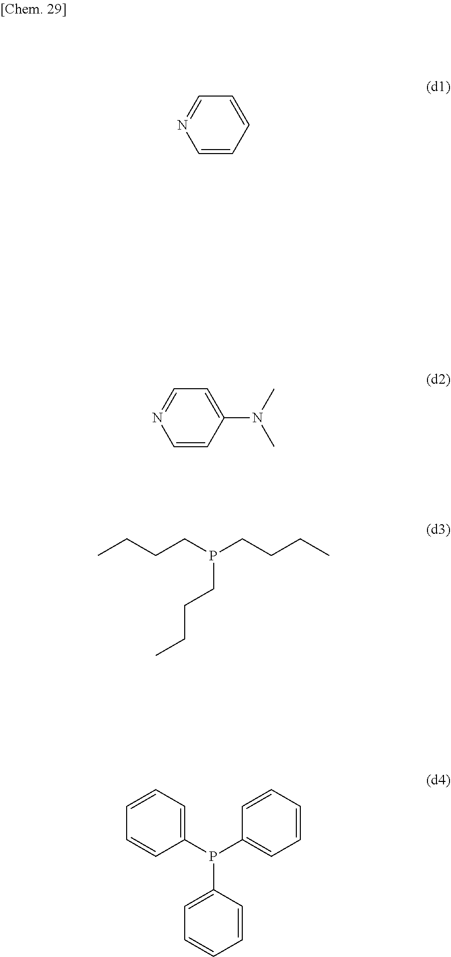

### Example 11

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst, 0.18 g of (D) pyridine as a co-catalyst and 60 g of propylene glycol monomethyl ether to prepare a raw material solution. The molar ratio of the component (C) to the component (D) is 1:1, and the equivalent ratio of the component (A) to the component (B) is 1:1.01.

Subsequently, this solution was heated under reflux at 121° C. and reacted for 1 to 6 hours to synthesize a polymer. GPC analysis of the polymer generated was performed, and the results showed that Mw was 6,400 one hour after reaching of the reflux temperature, Mw was 10,100 two hours after reaching of the reflux temperature, Mw was 10,500 four hours after reaching of the reflux temperature, Mw was 10,400 five hours after reaching of the reflux temperature, and Mw was 10,400 six hours after reaching of the reflux temperature. The weight average molecular weight Mw was stabilized after four hours after reaching of the reflux temperature.

### Example 21

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst, 0.26 g of (D) pyridine as a co-catalyst and 60 g of propylene glycol monomethyl ether to prepare a raw material solution. The molar ratio of the component (C) to the component (D) is 1:1.5, and the equivalent ratio of the component (A) to the component (B) is 1:1.01.

Subsequently, this solution was heated under reflux at 121° C. and reacted for 1 to 7 hours to synthesize a polymer. GPC analysis of the polymer generated was performed, and the results showed that Mw was 6,500 one hour after reaching of the reflux temperature, Mw was 8,100 two hours after reaching of the reflux temperature, Mw was 8,100 four hours after reaching of the reflux temperature, Mw was 8,000 five hours after reaching of the reflux temperature, Mw was 7,900 six hours after reaching of the reflux temperature, and Mw was 7,800 seven hours after reaching of the reflux temperature. The weight average molecular weight Mw was stabilized after two hours after reaching of the reflux temperature.

### Example 3

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst, 0.09 g of (D) pyridine as a co-catalyst and 60 g of propylene glycol monomethyl ether to prepare a raw material solution. The molar ratio of the component (C) to the component (D) is 1:0.5, and the equivalent ratio of the component (A) to the component (B) is 1:1.01.

Subsequently, this solution was heated under reflux at 121° C. and reacted for 1 to 7 hours to synthesize a polymer. GPC analysis of the polymer generated was performed, and the results showed that Mw was 8,500 one hour after reaching of the reflux temperature, Mw was 13,200 two hours after reaching of the reflux temperature, Mw was 15,000 four hours after reaching of the reflux temperature, Mw was 14,900 five hours after reaching of the reflux temperature, Mw was 14,800 six hours after reaching of the reflux temperature, and Mw was 14,600 seven hours after reaching of the reflux temperature. The weight average molecular weight Mw was stabilized after four hours after reaching of the reflux temperature.

### Example 4

A 200 mL reaction flask was charged with 12.6 g of (A) monoallyldiglycidylisocyanuric acid, 6.6 g of (B) adipic acid, 0.42 g of (C) ethyltriphenylphosphonium bromide as a polymerization catalyst, 0.09 g of (D) pyridine as a co-catalyst and 60 g of propylene glycol monomethyl ether to prepare a raw material solution. The molar ratio of the component (C) to the component (D) is 1.0:1.0, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 3.800 one hour after reaching of the reflux temperature. Mw was 9,900 two hours after reaching of the reflux temperature, Mw was 13,900 four hours after reaching of the reflux temperature, Mw was 14,000 five hours after reaching of the reflux temperature, Mw was 14,000 six hours after reaching of the reflux temperature, Mw was 13,900 seven hours after reaching of the reflux temperature, and the Mw was 13,900 eight hours after reaching of the reflux temperature. The weight average molecular weight Mw was stabilized after four hours after reaching of the reflux temperature.

### Example 51

A 500 mL reaction flask was charged with 31.5 g of (A) monoallyldiglycidylisocyanuric acid, 16.4 g of (B) adipic acid, 1.68 g of (C) ethyltriphenylphosphonium bromide as a polymerization catalyst, 0.09 g of (D) pyridine as a co-catalyst and 60 g of propylene glycol monomethyl ether to prepare a raw material solution. The molar ratio of the component (C) to the component (D) is 1:0.25, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 7,000 one hour after reaching of the reflux temperature, Mw was 14,600 two hours after reaching of the reflux temperature, Mw was 21,200 four hours after reaching of the reflux temperature, Mw was 25,600 five hours after reaching of the reflux temperature, Mw was 26,400 six hours after reaching of the reflux temperature, Mw was 27.300 seven hours after reaching of the reflux temperature, and Mw was 27.900 eight hours after reaching of the reflux temperature. The weight average molecular weight Mw was stabilized after six hours after reaching of the reflux temperature.

### Example 6

A 500 mL reaction flask was charged with 31.5 g of (A) monoallyldiglycidylisocyanuric acid, 16.4 g of (B) adipic acid, 1.26 g of (C) ethyltriphenylphosphonium bromide as a polymerization catalyst, 0.18 g of (D) pyridine as a co-catalyst and 60 g of propylene glycol monomethyl ether to prepare a raw material solution. The molar ratio of the component (C) to the component (D) is 1:0.67, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 5,200 one hour after reaching of the reflux temperature, Mw was 10.800 two hours after reaching of the reflux temperature, Mw was 15,900 four hours after reaching of the reflux temperature, Mw was 16,300 five hours after reaching of the reflux temperature, Mw was 16,300 six hours after reaching of the reflux temperature, Mw was 16,100 seven hours after reaching of the reflux temperature, and the Mw was 16,100 eight hours after reaching of the reflux temperature. The weight average molecular weight Mw was stabilized after four hours after reaching of the reflux temperature.

### Example 7

A 500 mL reaction flask was charged with 31.5 g of (A) monoallyldiglycidylisocyanuric acid, 16.4 g of (B) adipic acid, 0.84 g of (C) ethyltriphenylphosphonium bromide as a polymerization catalyst, 0.26 g of (D) pyridine as a co-catalyst and 60 g of propylene glycol monomethyl ether to prepare a raw material solution. The molar ratio of the component (C) to the component (D) is 0.67:1, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 3,000 one hour after reaching of the reflux temperature, Mw was 7,400 two hours after reaching of the reflux temperature, Mw was 12,500 four hours after reaching of the reflux temperature, Mw was 12,900 five hours after reaching of the reflux temperature, Mw was 12,800 six hours after reaching of the reflux temperature, Mw was 12,800 seven hours after reaching of the reflux temperature, and Mw was 12,800 eight hours after reaching of the reflux temperature. The weight average molecular weight Mw was stabilized after four hours after reaching of the reflux temperature.

### Example 8

A 500 mL reaction flask was charged with 31.5 g of (A) monoallyldiglycidylisocyanuric acid, 16.4 g of (B) adipic acid, 0.42 g of (C) ethyltriphenylphosphonium bromide as a polymerization catalyst, 0.35 g of (D) pyridine as a co-catalyst and 60 g of propylene glycol monomethyl ether to prepare a raw material solution. The molar ratio of the component (C) to the component (D) is 0.25:1, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 1,900 one hour after reaching of the reflux temperature, Mw was 4,800 two hours after reaching of the reflux temperature, Mw was 9,400 four hours after reaching of the reflux temperature, Mw was 9,800 five hours after reaching of the reflux temperature, Mw was 10,000 six hours after reaching of the reflux temperature, Mw was 10,000 seven hours after reaching of the reflux temperature, and the Mw was 10,000 eight hours after reaching of the reflux temperature. The weight average molecular weight Mw was stabilized after four hours after reaching of the reflux temperature.

### Comparative Example 1

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst and 60 g of propylene glycol monomethyl ether to prepare a raw material solution. The molar ratio of the component (C) to the component (D) is 1:0, and the equivalent ratio of the component (A) to the component (B) is 1:1.01.

Subsequently, this solution was heated under reflux at 121° C. and reacted for 1 to 6 hours to synthesize a polymer. GPC analysis of the polymer generated was performed, and the results showed that Mw was 8,800 one hour after reaching of the reflux temperature, Mw was 19,400 two hours after reaching of the reflux temperature, Mw was 40,000 four hours after reaching of the reflux temperature, Mw was 50,900 five hours after reaching of the reflux temperature, and Mw was 68.600 six hours after reaching of the reflux temperature. The weight average molecular weight Mw was not stabilized, and continued to increase.

### Comparative Example 2

A 200 mL reaction flask was charged with 12.6 g of (A) monoallyldiglycidylisocyanuric acid, 6.6 g of (B) adipic acid, 0.18 g of (D) pyridine as a co-catalyst and 60 g of propylene glycol monomethyl ether to prepare a raw material solution. The molar ratio of the component (C) to the component (D) is 0:1, and the equivalent ratio of the component (A) to the component (B) is 1:1.01.

Subsequently, this solution was heated under reflux at 121° C. and reacted for 1 to 8 hours to synthesize a polymer. GPC analysis of the polymer generated was performed, and the results showed that Mw was 1,300 one hour after reaching of the reflux temperature, Mw was 7,300 two hours after reaching of the reflux temperature, Mw was 9,600 four hours after reaching of the reflux temperature. Mw was 8,700 five hours after reaching of the reflux temperatures Mw was 7,900 six hours after reaching of the reflux temperature, Mw was 7,500 seven hours after reaching of the reflux temperature, and the Mw was 7200 eight hours after reaching of the reflux temperature. The eight average molecular weight Mw reached the maximum value four hours after reaching of the reflux temperature, and then continued to decrease.

The results of Examples to 8 and Comparative Examples 1 and 2 are collectively shown in Tables 1 and 2.

TABLE 1

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Comparative | (c1) | 5 | — | — | (a1) | 1 | (b1) | 1.01 | 121 (reflux) | 1 | 8,800 | 8.80 |
| Example 1 | | | | | | | | | | 2 | 19,400 | 8.08 |
| | | | | | | | | | | 4 | 40,000 | 14.29 |
| | | | | | | | | | | 5 | 50,900 | 17.55 |
| | | | | | | | | | | 6 | 68,600 | 22.87 |
| Example 2 | (c1) | 5 | (d1) | 7.5 | (a1) | 1 | (b1) | 1.01 | 121 (reflux) | 1 | 6,500 | 5.00 |
| | | | | | | | | | | 2 | 8,100 | 5.40 |
| | | | | | | | | | | 4 | 8,100 | 5.40 |
| | | | | | | | | | | 5 | 8,000 | 5.33 |
| | | | | | | | | | | 6 | 7,900 | 5.27 |
| | | | | | | | | | | 7 | 7,800 | 5.20 |
| Example 1 | (c1) | 5 | (d1) | 5 | (a1) | 1 | (b1) | 1.01 | 121 (reflux) | 1 | 6,400 | 4.92 |
| | | | | | | | | | | 2 | 10,100 | 5.94 |
| | | | | | | | | | | 4 | 10,500 | 5.83 |
| | | | | | | | | | | 5 | 10,400 | 5.78 |
| | | | | | | | | | | 6 | 10,400 | 5.78 |
| Example 3 | (c1) | 5 | (d1) | 2.5 | (a1) | 1 | (b1) | 1.01 | 121 (reflux) | 1 | 8,500 | 5.00 |
| | | | | | | | | | | 2 | 13,200 | 6.29 |
| | | | | | | | | | | 4 | 15,000 | 6.52 |
| | | | | | | | | | | 5 | 14,900 | 6.48 |
| | | | | | | | | | | 6 | 14,800 | 6.43 |
| | | | | | | | | | | 7 | 14,600 | 6.35 |
| Example 4 | (c1) | 2.5 | (d1) | 2.5 | (a1) | 1 | (b1) | 1.01 | 121 (reflux) | 1 | 3,800 | 3.80 |
| | | | | | | | | | | 2 | 9,900 | 5.50 |
| | | | | | | | | | | 4 | 13,900 | 6.32 |
| | | | | | | | | | | 5 | 14,000 | 6.36 |
| | | | | | | | | | | 6 | 14,000 | 6.36 |
| | | | | | | | | | | 7 | 13,900 | 6.32 |
| | | | | | | | | | | 8 | 13,900 | 6.32 |

TABLE 2

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Example 5 | (c1) | 4 | (d1) | 1 | (a1) | 1 | (b1) | 1.01 | 121 (reflux) | 1 | 7,000 | 4.67 |
| | | | | | | | | | | 2 | 14,600 | 6.08 |
| | | | | | | | | | | 4 | 21,200 | 7.31 |
| | | | | | | | | | | 5 | 25,600 | 8.26 |
| | | | | | | | | | | 6 | 26,400 | 8.25 |
| | | | | | | | | | | 7 | 27,300 | 8.53 |
| | | | | | | | | | | 8 | 27,900 | 8.45 |
| Example 6 | (c1) | 3 | (d1) | 2 | (a1) | 1 | (b1) | 1.01 | 121 (reflux) | 1 | 5,200 | 4.33 |
| | | | | | | | | | | 2 | 10,800 | 5.40 |
| | | | | | | | | | | 4 | 15,900 | 6.63 |
| | | | | | | | | | | 5 | 16,300 | 6.52 |
| | | | | | | | | | | 6 | 16,300 | 6.52 |
| | | | | | | | | | | 7 | 16,100 | 6.44 |
| | | | | | | | | | | 8 | 16,100 | 6.44 |
| Example 4 | (c1) | 2.5 | (d1) | 2.5 | (a1) | 1 | (b1) | 1.01 | 121 (reflux) | 1 | 3,800 | 3.80 |
| | | | | | | | | | | 2 | 9,900 | 5.50 |
| | | | | | | | | | | 4 | 13,900 | 6.32 |
| | | | | | | | | | | 5 | 14,000 | 6.36 |
| | | | | | | | | | | 6 | 14,000 | 6.36 |
| | | | | | | | | | | 7 | 13,900 | 6.32 |
| | | | | | | | | | | 8 | 13,900 | 6.32 |
| Example 7 | (c1) | 2 | (d1) | 3 | (a1) | 1 | (b1) | 1.01 | 121 (reflux) | 1 | 3,000 | 3.33 |
| | | | | | | | | | | 2 | 7,400 | 4.93 |
| | | | | | | | | | | 4 | 12,500 | 5.95 |
| | | | | | | | | | | 5 | 12,900 | 5.86 |
| | | | | | | | | | | 6 | 12,800 | 5.82 |
| | | | | | | | | | | 7 | 12,800 | 5.82 |
| | | | | | | | | | | 8 | 12,800 | 5.82 |
| Example 8 | (c1) | 1 | (d1) | 4 | (a1) | 1 | (b1) | 1.01 | 121 (reflux) | 1 | 1,900 | 2.71 |
| | | | | | | | | | | 2 | 4,800 | 4.00 |
| | | | | | | | | | | 4 | 9,400 | 5.53 |
| | | | | | | | | | | 5 | 9,800 | 5.44 |
| | | | | | | | | | | 6 | 10,000 | 5.56 |
| | | | | | | | | | | 7 | 10,000 | 5.56 |
| | | | | | | | | | | 8 | 10,000 | 5.56 |
| Comparative | — | — | (d1) | 5 | (a1) | 1 | (b1) | 1.01 | 121 (reflux) | 1 | 1,300 | 2.60 |
| Example 2 | | | | | | | | | | 2 | 7,300 | 4.06 |
| | | | | | | | | | | 4 | 9,600 | 4.36 |
| | | | | | | | | | | 5 | 8,700 | 4.14 |
| | | | | | | | | | | 6 | 7,900 | 4.16 |
| | | | | | | | | | | 7 | 7,500 | 4.17 |
| | | | | | | | | | | 8 | 7,200 | 4.24 |

### Example 9

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst, 0.58 g of (D) triphenylphosphine as a co-catalyst and 60 g of propylene glycol monomethyl ether to prepare a raw material solution. The molar ratio of the component (C) to the component (D) is 1:1, and the equivalent ratio of the component (A) to the component (B) is 1:1.01.

Subsequently, this solution was heated under reflux at 121° C. and reacted for 1 to 7 hours to synthesize a polymer. GPC analysis of the polymer generated was performed, and the results showed that Mw was 7,700 one hour after reaching of the reflux temperature, Mw was 12,500 two hours after reaching of the reflux temperature, Mw was 13,200 four hours after reaching of the reflux temperature, Mw was 13,200 five hours after reaching of the reflux temperature, Mw was 13,200 six hours after reaching of the reflux temperature, and Mw was 13,200 seven hours after reaching of the reflux temperature. The weight average molecular weight Mw was stabilized after four hours after reaching of the reflux temperature.

### Example 10

A 200 mL reaction flask was charged with 12.6 g of (A) monoallyldiglycidylisocyanuric acid, 6.6 g of (B) adipic acid, 0.84 g of (C) ethyltriphenylphosphonium bromide as a polymerization catalyst, 0.45 g of (D) tributylphosphine as a co-catalyst and 60 g of propylene glycol monomethyl ether to prepare a raw material solution. The molar ratio of the component (C) to the component (D) is 1:1, and the equivalent ratio of the component (A) to the component (B) is 1:1.01.

Subsequently, this solution was heated under reflux at 121° C. and reacted for 1 to 6 hours to synthesize a polymer. GPC analysis of the polymer generated was performed, and the results showed that Mw was 6,800 one hour after reaching of the reflux temperature, Mw was 10,300 two hours after reaching of the reflux temperature, Mw was 10,900 four hours after reaching of the reflux temperature, Mw was 10,900 five hours after reaching of the reflux temperature, and Mw was 10,800 six hours after reaching of the reflux temperature. The weight average molecular weight Mw was stabilized after four hours after reaching of the reflux temperature.

The results of Example 9 and 10 are collectively shown in Table 3.

TABLE 3

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Example 9 | (c1) | 5 | (d4) | 5 | (a1) | 1 | (b1) | 1.01 | 121 (reflux) | 1 | 7,700 | 5.50 |
| | | | | | | | | | | 2 | 12,500 | 6.94 |
| | | | | | | | | | | 4 | 13,200 | 7.33 |
| | | | | | | | | | | 5 | 13,200 | 7.33 |
| | | | | | | | | | | 6 | 13,200 | 7.33 |
| | | | | | | | | | | 7 | 13,200 | 7.33 |
| Example 10 | (c1) | 5 | (d3) | 5 | (a1) | 1 | (b1) | 1.01 | 121 (reflux) | 1 | 6,800 | 5.23 |
| | | | | | | | | | | 2 | 10,300 | 6.06 |
| | | | | | | | | | | 4 | 10,900 | 6.41 |
| | | | | | | | | | | 5 | 10,900 | 6.41 |
| | | | | | | | | | | 6 | 10,800 | 6.35 |

### Example 11

A 200 mL reaction flask was charged with 11.0 g of (A) monoallyldiglycidylisocyanuric acid, 8.3 g of (B) 3,3-dithiopropionic acid, 0.73 g of (C) ethyltriphenylphosphonium bromide as a polymerization catalyst, 0.15 g of (D) pyridine as a co-catalyst and 60 g of propylene glycol monomethyl ether to prepare a raw material solution. The molar ratio of the component (C) to the component (D) is 1:1, and the equivalent ratio of the component (A) to the component (B) is 1:1.01.

Subsequently, this solution was heated under reflux at 121° C. and reacted for 1 to 7 hours to synthesize a polymer. GPC analysis of the polymer generated was performed, and the results showed that Mw was 1,800 one hour after reaching of the reflux temperature, Mw was 1,800 two hours after reaching of the reflux temperature, Mw was 1,800 four hours after reaching of the reflux temperature, Mw was 1,800 five hours after reaching of the reflux temperature, Mw was 1,700 six hours after reaching of the reflux temperature, and Mw was 1,800 seven hours after reaching of the reflux temperature. The weight average molecular weight Mw was stabilized after one hour after reaching of the reflux temperature.

### Comparative Example 3

A 200 mL reaction flask was charged with 11.0 g of (A) monoallyldiglycidylisocyanuric acid, 8.3 g of (B) 3,3-dithiopropionic acid, 0.73 g of (C) ethyltriphenylphosphonium bromide as a polymerization catalyst and 60 g of propylene glycol monomethyl ether to prepare a raw material solution. The molar ratio of the component (C) to the component (D) is 1:0, and the equivalent ratio of the component (A) to the component (B) is 1:1.01.

Subsequently, this solution was heated under reflux at 121° C. and reacted for 1 to 7 hours to synthesize a polymer. GPC analysis of the polymer generated was performed, and the results showed that Mw was 2,000 one hour after reaching of the reflux temperature, Mw was 2,900 two hours after reaching of the reflux temperature, Mw was 3,500 four hours after reaching of the reflux temperature, Mw was 3,700 five hours after reaching of the reflux temperature, Mw was 3,800 six hours after reaching of the reflux temperature, and Mw was 4,000 seven hours after reaching of the reflux temperature. The weight average molecular weight Mw was not stabilized, and continued to increase.

The results of Example 11 and Comparative Example 3 are collectively shown in Table 4.

TABLE 4

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Example 11 | (c1) | 5 | (d1) | 5 | (a1) | 1 | (b2) | 1.01 | 121 (reflux) | 1 | 1,800 | 3.00 |
| | | | | | | | | | | 2 | 1,800 | 3.00 |
| | | | | | | | | | | 4 | 1,800 | 3.00 |
| | | | | | | | | | | 5 | 1,800 | 3.00 |
| | | | | | | | | | | 6 | 1,700 | 2.83 |
| | | | | | | | | | | 7 | 1,800 | 2.57 |
| Comparative | (c1) | 5 | — | — | (a1) | 1 | (b2) | 1.01 | 121 (reflux) | 1 | 2,000 | 2.86 |
| Example 3 | | | | | | | | | | 2 | 2,900 | 3.63 |
| | | | | | | | | | | 4 | 3,500 | 3.89 |
| | | | | | | | | | | 5 | 3,700 | 4.11 |
| | | | | | | | | | | 6 | 3,800 | 4.22 |
| | | | | | | | | | | 7 | 4,000 | 4.44 |

### Example 12

A 200 mL reaction flask was charged with 12.8 g of (A) monoallyldiglycidylisocyanuric acid, 10.4 g of (B) bisphenol A, 0.85 g of (C) ethyltriphenylphosphonium bromide as a polymerization catalyst, 0.05 g of (D) pyridine as a co-catalyst and 56 g of propylene glycol monomethyl ether to prepare a raw material solution. The molar ratio of the component (C) to the component (D) is 1:0.3, and the equivalent ratio of the component (A) to the component (B) is 1:1.005.

Subsequently, this solution was heated under reflux at 121° C. and reacted for 1 to 7 hours to synthesize a polymer. GPC analysis of the polymer generated was performed, and the results showed that Mw was 4,400 one hour after reaching of the reflux temperature, Mw was 5,600 two hours after reaching of the reflux temperature, Mw was 5,600 five hours after reaching of the reflux temperature, Mw was 5,600 six hours after reaching of the reflux temperature, and Mw was 5,500 seven hours after reaching of the reflux temperature. The weight average molecular weight Mw was stabilized after two hours after reaching of the reflux temperature.

### Comparative Example 4

A 200 mL reaction flask was charged with 12.8 g of (A) monoallyldiglycidylisocyanuric acid, 10.4 g of (B) bisphenol A, 0.85 g of (C) ethyltriphenylphosphonium bromide as a polymerization catalyst and 56 g of propylene glycol monomethyl ether to prepare a raw material solution. The molar ratio of the component (C) to the component (D) is 1:0, and the equivalent ratio of the component (A) to the component (B) is 1:1.005.

Subsequently, this solution was heated under reflux at 121° C. and reacted for 1 to 7 hours to synthesize a polymer. GPC analysis of the polymer generated was performed, and the results showed that Mw was 2,100 one hour after reaching of the reflux temperature, Mw was 3,800 two hours after reaching of the reflux temperature, Mw was 5,300 four hours after reaching of the reflux temperature, Mw was 5,700 five hours after reaching of the reflux temperature, Mw was 6,000 six hours after reaching of the reflux temperature, and Mw was 6,300 seven hours after reaching of the reflux temperature. The weight average molecular weight Mw was not stabilized, and continued to increase.

The results of Example 12 and Comparative Example 4 are collectively shown in Table 5.

TABLE 5

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Example 12 | (c1) | 5 | (d1) | 1.5 | (a1) | 1 | (b4) | 1.005 | 121 (reflux) | 1 | 4,400 | 2.44 |
| | | | | | | | | | | 2 | 5,600 | 2.55 |
| | | | | | | | | | | 5 | 5,600 | 2.55 |
| | | | | | | | | | | 6 | 5,600 | 2.55 |
| | | | | | | | | | | 7 | 5,500 | 2.62 |
| Comparative | (c1) | 5 | — | — | (a1) | 1 | (b4) | 1.005 | 121 (reflux) | 1 | 2,100 | 2.10 |
| Example 4 | | | | | | | | | | 2 | 3,800 | 2.38 |
| | | | | | | | | | | 4 | 5,300 | 2.52 |
| | | | | | | | | | | 5 | 5,700 | 2.59 |
| | | | | | | | | | | 6 | 6,000 | 2.61 |
| | | | | | | | | | | 7 | 6,300 | 2.74 |

### Example 13

A 500 mL reaction flask was charged with 34.2 g of (A) monoallyldiglycidylisocyanuric acid, 23.5 g of (B) barbital, 2.3 g of (C) ethyltriphenylphosphonium bromide as a polymerization catalyst, 0.29 g of (D) pyridine as a co-catalyst and 240 g of propylene glycol monomethyl ether to prepare a raw material solution. The molar ratio of the component (C) to the component (D) is 1:0.6, and the equivalent ratio of the component (A) to the component (B) is 1:1.04.

Subsequently, this solution was heated under reflux at 121° C. and reacted for 1 to 6 hours to synthesize a polymer. GPC analysis of the polymer generated was performed, and the results showed that Mw was 7,600 one hour after reaching of the reflux temperature, Mw was 10,400 two hours after reaching of the reflux temperature, Mw was 11,300 four hours after reaching of the reflux temperature, and Mw was 11,400 six hours after reaching of the reflux temperature. The weight average molecular weight Mw was stabilized after four hours after reaching of the reflux temperature.

### Comparative Example 5

A 500 mL reaction flask was charged with 34.2 g of (A) monoallyldiglycidylisocyanuric acid, 23.5 g of (B) barbital, 2.3 g of (C) ethyltriphenylphosphonium bromide as a polymerization catalyst and 240 g of propylene glycol monomethyl ether to prepare a raw material solution. The molar ratio of the component (C) to the component (D) is 1:0, and the equivalent ratio of the component (A) to the component (B) is 1:1.04.

Subsequently, this solution was heated under reflux at 121° C. and reacted for 1 to 8 hours to synthesize a polymer. GPC analysis of the polymer generated was performed, and the results showed that Mw was 5,400 one hour after reaching of the reflux temperature, Mw was 8,900 two hours after reaching of the reflux temperature, Mw was 12,100 four hours after reaching of the reflux temperature, Mw was 14,100 six hours after reaching of the reflux temperature, and Mw was 15,800 eight hours after reaching of the reflux temperature. The weight average molecular weight Mw was not stabilized, and continued to increase.

### Example 14

A 500 mL reaction flask was charged with 34.1 g of (A) monoallyldiglycidylisocyanuric acid, 23.4 g of (B) barbital, 2.1 g of (C) tetrabutylphosphonium bromide as a polymerization catalyst, 0.48 g of (D) pyridine as a co-catalyst and 240 g of propylene glycol monomethyl ether to prepare a raw material solution. The molar ratio of the component (C) to the component (D) is 1:1, and the equivalent ratio of the component (A) to the component (B) is 1:1.04.

Subsequently, this solution was heated under reflux at 121° C. and reacted for 1 to 8 hours to synthesize a polymer. GPC analysis of the polymer generated was performed, and the results showed that Mw was 4,700 one hour after reaching of the reflux temperature. Mw was 7,000 two hours after reaching of the reflux temperature, Mw was 7,900 four hours after reaching of the reflux temperature, Mw was 7,900 six hours after reaching of the reflux temperature, and Mw was 7,900 eight hours after reaching of the reflux temperature. The weight average molecular weight Mw was stabilized after four hours after reaching of the reflux temperature.

### Example 15

A 500 mL reaction flask was charged with 34.0 g of (A) monoallyldiglycidylisocyanuric acid, 23.3 g of (B) barbital, 2.1 g of (C) tetrabutylphosphonium bromide as a polymerization catalyst, 0.74 g of (D) N,N-dimethyl-4-aminopyridine as a co-catalyst and 240 g of propylene glycol monomethyl ether to prepare a raw material solution. The molar ratio of the component (C) to the component (D) is 1:1, and the equivalent ratio of the component (A) to the component (B) is 1:1.04.

Subsequently, this solution was heated under reflux at 121° C. and reacted for 1 to 8 hours to synthesize a polymer. GPC analysis of the polymer generated was performed, and the results showed that Mw was 5,700 one hour after reaching of the reflux temperature, Mw was 5,800 two hours after reaching of the reflux temperature, Mw was 5,900 four hours after reaching of the reflux temperature, Mw was 5,900 six hours after reaching of the reflux temperature, and Mw was 5,900 eight hours after reaching of the reflux temperature. The weight average molecular weight Mw was stabilized after two hours after reaching of the reflux temperature.

### Comparative Example 6

A 500 mL reaction flask was charged with 34.2 g of (A) monoallyldiglycidylisocyanuric acid, 23.5 g of (B) barbital, 2.1 g of (C) tetrabutylphosphonium bromide as a polymerization catalyst and 240 g of propylene glycol monomethyl ether to prepare a raw material solution. The molar ratio of the component (C) to the component (D) is 1:0, and the equivalent ratio of the component (A) to the component (B) is 1:1.04.

Subsequently, this solution was heated under reflux at 121° C. and reacted for 1 to 8 hours to synthesize a polymer. GPC analysis of the polymer generated was performed, and the results showed that Mw was 2,900 one hour after reaching of the reflux temperature, Mw was 5,600 two hours after reaching of the reflux temperature, Mw was 8,300 four hours after reaching of the reflux temperature, Mw was 10,300 six hours after reaching of the reflux temperature, and Mw was 11,900) eight hours after reaching of the reflux temperature. The weight average molecular weight Mw was not stabilized, and continued to increase.

The results of Examples 13 to 15 and Comparative Examples 5 and 6 are collectively shown in Table 6.

TABLE 6

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Example | (c1) | 5 | (d1) | 3 | (a1) | 1 | (b3) | 1.04 | 121 ( [symbol] ) | 1 | 7,600 | 5.07 |
| 13 | | | | | | | | | | 2 | 10,400 | 6.12 |
| | | | | | | | | | | 4 | 11,300 | 6.65 |
| | | | | | | | | | | 6 | 11,400 | 6.71 |
| Compar- | (c1) | 5 | — | — | (a1) | 1 | (b3) | 1.04 | 121 ( [symbol] ) | 1 | 5,400 | 3.86 |
| ative | | | | | | | | | | 2 | 8,900 | 5.56 |
| Example | | | | | | | | | | 4 | 12,100 | 6.72 |
| 5 | | | | | | | | | | 6 | 14,100 | 7.83 |
| | | | | | | | | | | 8 | 15,800 | 8.78 |
| Example | (c1) | 5 | (d1) | 5 | (a1) | 1 | (b3) | 1.04 | 121 ( [symbol] ) | 1 | 4,700 | 3.62 |
| 14 | | | | | | | | | | 2 | 7,000 | 5.00 |
| | | | | | | | | | | 4 | 7,900 | 5.27 |
| | | | | | | | | | | 6 | 7,900 | 5.27 |
| | | | | | | | | | | 8 | 7,900 | 5.27 |
| Example | (c2) | 5 | (d2) | 5 | (a1) | 1 | (b3) | 1.04 | 121 ( [symbol] ) | 1 | 5,700 | 4.38 |
| 15 | | | | | | | | | | 2 | 5,800 | 4.46 |
| | | | | | | | | | | 4 | 5,900 | 4.54 |
| | | | | | | | | | | 6 | 5,900 | 4.54 |
| | | | | | | | | | | 8 | 5,900 | 4.54 |
| Compar- | (c2) | 5 | — | — | (a1) | 1 | (b3) | 1.04 | 121 ( [symbol] ) | 1 | 2,900 | 2.90 |
| ative | | | | | | | | | | 2 | 5,600 | 4.00 |
| Example | | | | | | | | | | 4 | 8,300 | 5.53 |
| 6 | | | | | | | | | | 6 | 10,300 | 6.44 |
| | | | | | | | | | | 8 | 11,900 | 7.44 |

### Example 16

A 200 mL reaction flask was charged with 15.3 g of (A) terephthalic acid diglycidyl ester, 7.7 g of (B) adipic acid, 1.0 g of (C) ethyltriphenylphosphonium bromide as a polymerization catalyst, 0.21 g of (D) pyridine as a co-catalyst and 56 g of propylene glycol monomethyl ether to prepare a raw material solution. The molar ratio of the component (C) to the component (D) is 1:1, and the equivalent ratio of the component (A) to the component (B) is 1:1.001.

Subsequently, this solution was heated under reflux at 105° C. and reacted for 1 to 6 hours to synthesize a polymer. GPC analysis of the polymer generated was performed, and the results showed that Mw was 5,500 one hour after reaching of the reflux temperature, Mw was 11,100 two hours after reaching of the reflux temperature, Mw was 13,000 four hours after reaching of the reflux temperature, Mw was 13,000 five hours after reaching of the reflux temperature, and Mw was 13,000 six hours after reaching of the reflux temperature. The weight average molecular weight Mw was stabilized after four hours after reaching of the reflux temperature.

### Comparative Example 7

A 200 mL reaction flask was charged with 15.3 g of (A) terephthalic acid diglycidyl ester, 7.7 g of (B) adipic acid, 1.0 g of (C) ethyltriphenylphosphonium bromide as a polymerization catalyst and 56 g of propylene glycol monomethyl ether to prepare a raw material solution. The molar ratio of the component (C) to the component (D) is 1:0, and the equivalent ratio of the component (A) to the component (B) is 1:1.001.

Subsequently, this solution was heated under reflux at 105° C. and reacted for 1 to 6 hours to synthesize a polymer. GPC analysis of the polymer generated was performed, and the results showed that Mw was 5,100 one hour after reaching of the reflux temperature, Mw was 14,700 two hours after reaching of the reflux temperature, Mw was 19,900 four hours after reaching of the reflux temperature, Mw was 20,400 five hours after reaching of the reflux temperature, and Mw was 20,500 six hours after reaching of the reflux temperature. The weight average molecular weight Mw was not stabilized, and continued to increase.

The results of Example 16 and Comparative Example 7 are collectively shown in Table 7.

TABLE 7

| | (C) | | | | (A) | | (B) | | | | | |
|---|---|---|---|---|---|---|---|---|---|---|---|---|
| | Polymerization | | (D) | | Epoxy | | Reactive | | Reaction | | | |
| | catalyst | | Co-catalyst | | compound | | compound | | conditions | | | |
| | | Compounding | | Compounding | | Compounding | | Compounding | Internal | | | |
| | | amount | | amount | | amount | | amount | temperature | Time | | |
| | Type | (mol %) | Type | (mol %) | Type | (equivalent) | Type | (equivalent) | (° C.) | (h) | Mw | Mw/Mn |
| Compar- | (c1) | 5 | — | — | (a2) | 1 | (b1) | 1.001 | 105 | 1 | 5,100 | 4.64 |
| ative | | | | | | | | | | 2 | 14,700 | 6.68 |
| Example | | | | | | | | | | 4 | 19,900 | 7.96 |
| 7 | | | | | | | | | | 5 | 20,400 | 7.85 |
| | | | | | | | | | | 6 | 20,500 | 7.59 |
| Example | (c1) | 5 | (d1) | 5 | (a2) | 1 | (b1) | 1.001 | 105 | 1 | 5,500 | 5.00 |
| 16 | | | | | | | | | | 2 | 11,100 | 6.94 |
| | | | | | | | | | | 4 | 13,000 | 7.22 |
| | | | | | | | | | | 5 | 13,000 | 7.22 |
| | | | | | | | | | | 6 | 13,000 | 7.22 |

1. A method for producing a polymer, comprising reacting (A) an epoxy compound having two or more epoxy groups in a molecule with (B) a reactive compound having two or more functional groups reactive with an epoxy group in the molecule, in the presence of (C) a polymerization catalyst and (D) a co-catalyst.

2. The method for producing a polymer according to claim 1, wherein the component (C) is an onium salt having one or more quaternary Group 15 element structures.

3. The method for producing a polymer according to claim 2, wherein the Group 15 element of the component (C) is nitrogen or phosphorus.

4. The method for producing a polymer according to claim 2, wherein a substituent in the Group 15 element structure of the component (C) is at least one selected from an alkyl group having 1 to 20 carbon atoms, an aryl group having 6 to 20 carbon atoms, and an aralkyl group having 7 to 20 carbon atoms.

5. The method for producing a polymer according to claim 2, wherein a counter anion in the onium salt is selected from a halide ion, a nitrate ion, a sulfate ion, an acetate ion, a formate ion, a hydroxide ion, and a sulfonate ion having an alkyl group having 1 to 20 carbon atoms or an aryl group having 6 to 20 carbon atoms.

6. The method for producing a polymer according to claim 1, wherein the component (D) is a compound having a primary to tertiary Group 15 element structure or a heteroaryl compound containing a Group 15 element in an aromatic ring.

7. The method for producing a polymer according to claim 6, wherein the Group 15 element of the component (D) is nitrogen or phosphorus.

8. The method for producing a polymer according to claim 6, wherein the component (D) is a compound having a tertiary Group 15 element structure or a heteroaryl compound containing a Group 15 element in the aromatic ring.

9. The method for producing a polymer according to claim 6, wherein a substituent in the Group 15 element structure of the component (D) is at least one selected from an alkyl group having 1 to 20 carbon atoms, an aryl group having 6 to 20 carbon atoms, and an aralkyl group having 7 to 20 carbon atoms.

10. The method for producing a polymer according to claim 1, wherein the component (A) is one or more selected from a diepoxy compound, a triepoxy compound, a tetraepoxy compound, and a polymer having an epoxy group.

11. The method for producing a polymer according to claim 1, wherein the functional group of the component (B) is a hydroxyl group, a formyl group, a carboxy group, an amino group, an imino group, an azo group, an azi group, a thiol group, a sulfo group, an amide group, an imide group, a thiocarboxy group, a dithiocarboxy group, a phosphate group, a phosphite group, a phosphonate group, a phosphonite group, a phosphinate group, a phosphinite group, a phosphine group, an acid anhydride or an acid chloride.

12. The method for producing a polymer according to claim 1, wherein an equivalent ratio of epoxy groups of the component (A) to functional groups of the component (B) is 0.1:1.0 to 1.0:0.1 in terms of (A):(B).

13. The method for producing a polymer according to claim 1, wherein a compounding ratio (molar ratio) of the component (C) to the component (D) is 0.1:1.0 to 1.0:0.1, and a total amount of the component (C) and the component (D) is 0.0001 to 0.5 mol per 1 mol of the component (A).

14. The method for producing a polymer according to claim 1, wherein further, one or more selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, 7-butyrolactone, N-methylpyrrolidone, N,N-dimethylformamide and N,N-dimethylacetamide are used as organic solvents.

15. The method for producing a polymer according to claim 14, wherein an amount of the organic solvent used is 0.1 to 100 parts by weight per 1.0 part by weight of the component (A).

16. The method for producing a polymer according to claim 1, wherein a reaction temperature is 25 to 200° C.

17. A method for producing a resist lower layer film forming composition, the method comprising mixing a polymer obtained by the production method according to claim 1 with an organic solvent.
